(19) United States
(12) Patent Application Publication
(10) Pub. No.: US 2017/0129231 A1
(43) Pub. Date: May 11, 2017

(54) LAMINATED POLYESTER FILM AND A PRODUCTION METHOD THEREOF, SOLAR CELL PROTECTIVE SHEET, AND SOLAR CELL MODULE

(71) Applicant: FUJIFILM CORPORATION, Tokyo (JP)

(72) Inventors: Hideki TOMIZAWA, Fujinomiya-shi (JP); Maki MIFUNE, Fujinomiya-shi (JP)

(21) Appl. No.: 15/415,871

(22) Filed: Jan. 26, 2017

Related U.S. Application Data
(63) Continuation of application No. PCT/JP2015/068547, filed on Jun. 26, 2015.

(30) Foreign Application Priority Data
Jul. 31, 2014 (JP) 2014-156943

(51) Int. Cl. B32B 27/36; B29C 55/14; H01L 31/049; B32B 27/32; B32B 27/30; B05D 3/04; B29C 37/00

(52) U.S. Cl. CPC B32B 27/36; B05D 3/0413; B29C 55/14; B29C 37/0025; B32B 27/32; B32B 27/308; H01L 31/049; B29K 2067/00

(57) ABSTRACT

An embodiment of the present invention provides a laminated polyester film including: a biaxially oriented polyester film which is produced by stretching an un-stretched polyester film in a first direction and stretching the resultant in a second direction perpendicular to the first direction along a film surface and has a small endothermic peak temperature of 160° C. or higher and 210° C. or lower, which is derived from a heat setting temperature measured by differential scanning calorimetry; and an undercoat layer which is formed by applying an undercoat layer forming composition onto one surface of the polyester film stretched in the first direction before being stretched in the second direction, and stretching the resultant in the second direction, and has a modulus of elasticity of 0.7 GPa or higher, a production method thereof, and a solar cell protective sheet and a solar cell module which include the laminated polyester film.

### CROSS-REFERENCE TO RELATED APPLICATIONS

This application is a continuation application of International Application No. PCT/JP2015/068547, filed Jun. 26, 2015, the disclosure of which is incorporated herein by reference in its entirety. Further, this application claims priority from Japanese Patent Application No. 2014-156943, filed Jul. 31, 2014, the disclosure of which is incorporated herein by reference in its entirety.

### BACKGROUND OF THE INVENTION

1. Field of the Invention

An embodiment of the present invention relates to a laminated polyester film, a production method thereof, a solar cell protective sheet, and a solar cell module.

2. Description of the Related Art

A polyester film has been used in many fields including a solar cell protective sheet, an optical film, a tracing film, a packing film, a magnetic tape, an insulating tape, and the like. In a case where the polyester film is used in these applications, a different material from the polyester film is generally adhered to the polyester film for use.

For example, a case of using a polyester film in a solar cell protective sheet is exemplified. A solar cell module has a structure in which a solar cell, in which a solar cell element is sealed with a sealing material, is interposed between a front substrate disposed on the front surface side on which, generally, sunlight is incident and a rear surface protective sheet disposed on the side (rear surface side) opposite to the front surface side on which sunlight is incident. As the sealing material, an EVA (ethylene-vinyl acetate copolymer) resin or the like is generally used. That is, in a case of using the polyester film in solar cell applications, adhesiveness between the polyester film and the sealing material is required.

Furthermore, an environment in which a solar cell module is generally used is an environment always exposed to outdoor weather such as the wind and the rain. Therefore, weather resistance of the solar cell protective sheet is one of the important issues.

It is important for the solar cell protective sheet to have a degree of weather resistance (wet heat stability) at which the sealing material adjacent to the solar cell protective sheet and the solar cell protective sheet do not peel away from each other, and in a case where the solar cell protective sheet has a laminated structure, peeling between the layers in the solar cell protective sheet does not occur, even in such an environment (for example, in a wet heat environment).

Here, various solar cell protective sheets for the purpose of an improvement in weather resistance have been proposed.

For example, JP2014-76632A proposes a laminated film including a polyester film and a coating layer laminated on at least one surface of the polyester film, in which the coating layer includes an acid-modified polyolefin resin and a basic compound having a boiling point of 200° C. or lower, and the polyester film includes a compound derived from the acid-modified polyolefin resin included in the coating layer. By forming the laminated film having the coating layer, which is formed by using the polyolefin resin, in an in-line coating method, the laminated film is considered to have excellent adhesiveness and water proofness.

JP2012-189665A proposes a biaxially oriented polyethylene terephthalate film in which a coating layer is provided by in-line coating on a polyethylene terephthalate film subjected to a heat setting treatment process at 220° C. or higher and 230° C. or lower. The biaxially oriented polyethylene terephthalate film is considered to achieve both optical axis accuracy of a polyester film for optical film applications and thermal dimensional stability of a film.

### SUMMARY OF THE INVENTION

However, like the laminated film disclosed in JP2014-76632A, although a laminated polyester film having a layer formed by using a polyolefin resin has good adhesiveness to a sealing material formed of an ethylene-vinyl acetate copolymer (EVA) or the like, cohesive fracture is likely to occur in the polyester film as a base material. As a result, there is concern that the polyester film may peel away from the sealing material.

On the other hand, by increasing a heat setting temperature and disturbing molecular orientation, the strength of the polyester film is increased, and resistance to cohesive fracture (cohesive fracture resistance) is improved. However, when the heat setting temperature is increased, the weather resistance (wet heat stability) of the polyester film tends to decrease.

Therefore, in a current situation, a laminated polyester film which achieves both cohesive fracture resistance and weather resistance (wet heat stability) is not yet provided.

An embodiment of the present invention has been made taking the foregoing circumstances into consideration, an object of the embodiment of the present invention is to provide a laminated polyester film which achieves both cohesive fracture resistance and weather resistance (wet heat stability) and a production method thereof, a solar cell protective sheet, and a solar cell module having long-term durability, and the embodiment of the present invention aims to achieve the object.

Specific means for solving the problems includes the following aspects.

<1> A laminated polyester film comprising: a biaxially oriented polyester film which is produced by stretching an un-stretched polyester film in a first direction and stretching the resultant in a second direction perpendicular to the first direction along a film surface and has a small endothermic peak temperature of 160° C. or higher and 210° C. or lower, which is derived from a heat setting temperature measured by differential scanning calorimetry; and an undercoat layer which is formed by applying an undercoat layer forming composition onto one surface of the polyester film stretched in the first direction before being stretched in the second direction, and stretching the resultant in the second direction, and has a modulus of elasticity of 0.7 GPa or higher.

<2> The laminated polyester film described in <1>, in which the undercoat layer includes an acrylic resin, and the content of the acrylic resin in a resin component included in the undercoat layer is 50 mass % or more.

<3> The laminated polyester film described in <2>, in which the content of the acrylic resin in the resin component included in the undercoat layer is 75 mass % or more.

<4> The laminated polyester film described in <2> or <3>, in which the acrylic resin included in the undercoat layer has a styrene skeleton.

<5> The laminated polyester film described in any one of <1> to <4>, in which the modulus of elasticity of the undercoat layer is 1.0 GPa or higher.

<6> The laminated polyester film described in any one of <1> to <5>, in which the modulus of elasticity of the undercoat layer is 1.3 GPa or higher.

<7> The laminated polyester film described in any one of <1> to <6>, in which the small endothermic peak temperature of the biaxially oriented polyester film is 170° C. or higher and 200° C. or lower.

<8> The laminated polyester film described in any one of <1> to <7>, in which the small endothermic peak temperature of the biaxially oriented polyester film is 180° C. or higher and 190° C. or lower.

<9> The laminated polyester film described in any one of <1> to <8>, in which the undercoat layer further includes an oxazoline-based crosslinking agent.

<10> A solar cell protective sheet comprising: the laminated polyester film described in any one of <1> to <9>; and a resin layer including an acrylic resin disposed on an undercoat layer of the laminated polyester film.

<11> The solar cell protective sheet described in <10>, in which the resin layer has a structure in which at least two layers are laminated, and an outermost layer which is farthest from the laminated polyester film includes an acrylic resin and a polyolefin resin.

<12> The solar cell protective sheet described in <10> or <11>, in which a weather-resistant layer is provided on a side of the laminated polyester film opposite to a side on which the undercoat layer is provided.

<13> The solar cell protective sheet described in <12>, in which the weather-resistant layer has a structure in which at least two layers are laminated, and a weather-resistant layer farthest from the laminated polyester film includes a fluorine-based resin.

<14> A solar cell module comprising: the solar cell protective sheet described in any one of <10> to <13>.

<15> A production method of a laminated polyester film comprising: a process of stretching an un-stretched polyester film in a first direction; a process of applying an undercoat layer forming composition onto one surface of the polyester film stretched in the first direction; a process of forming an undercoat layer having a modulus of elasticity of 0.7 GPa or higher by stretching the polyester film, to which the undercoat layer forming composition is applied, in a second direction perpendicular to the first direction along a film surface; and a heat setting process of carrying out a heat setting treatment on the polyester film in which the undercoat layer is formed, at 165° C. or higher and 215° C. or lower, in which a biaxially oriented polyester film in which the undercoat layer is formed is produced.

According to the embodiment of the present invention, a laminated polyester film which achieves both cohesive fracture resistance and weather resistance (wet heat stability) and a production method thereof, a solar cell protective sheet, and a solar cell module having long-term durability.

### DESCRIPTION OF THE PREFERRED EMBODIMENTS

<Laminated Polyester Film>

A laminated polyester film includes: a biaxially oriented polyester film (hereinafter, appropriately referred to as a base material) which is produced by stretching an un-stretched polyester film in a first direction and stretching the resultant in a second direction perpendicular to the first direction along a film surface and has a small endothermic peak temperature of 160° C. or higher and 210° C. or lower, which is derived from a heat setting temperature measured by differential scanning calorimetry; and an undercoat layer which is formed by applying an undercoat layer forming composition onto one surface of the polyester film stretched in the first direction before being stretched in the second direction, and then stretching the resultant in the second direction, and has a modulus of elasticity of 0.7 GPa or higher.

As the laminated polyester film includes the above-described configuration, cohesive fracture is less likely to occur, and both cohesive fracture resistance and weather resistance (wet heat stability) can be achieved.

Actions of an embodiment of the present invention are not clear. However, the inventors have assumed the following.

That is, it is thought that as the laminated polyester film includes the undercoat layer having a modulus of elasticity of 0.7 GPa or higher, cohesive fracture in the biaxially oriented polyester film, which is the base material, can be effectively prevented. Therefore, although cohesive fracture in a base material is prevented by increasing a heat setting temperature of the base material and increasing the strength of the base material in the related art, it becomes possible to perform a treatment at a temperature lower than the heat setting temperature of the base material in the related art. The heat setting temperature of the base material contributes to wet heat stability, and when the heat setting temperature is in a predetermined range, wet heat stability is improved. Meanwhile, when the heat setting temperature deviates from the predetermined temperature range, wet heat stability decreases. That is, it is thought that as the laminated polyester film uses the biaxially oriented polyester film having a small endothermic peak temperature of 160° C. or higher and 210° C. or lower, which is derived from the heat setting temperature measured by differential scanning calorimetry (DSC), as the base material, wet heat stability can be maintained.

It is thought that in a combination of these, the laminated polyester film can achieve both cohesive fracture resistance and weather resistance (wet heat stability).

[Biaxially Oriented Polyester Film]

The laminated polyester film includes the biaxially oriented polyester film which is produced by stretching the un-stretched polyester film in the first direction and stretching the resultant in the second direction perpendicular to the first direction along the film surface and has a small endothermic peak temperature of 160° C. or higher and 210° C. or lower, which is derived from the heat setting temperature measured by differential scanning calorimetry.

(Small Endothermic Peak Temperature)

The small endothermic peak temperature derived from the heat setting temperature measured by differential scanning calorimetry reflects a treatment temperature (heat setting temperature) in a heat setting process during the production of the laminated polyester film.

In a case where the small endothermic peak temperature derived from the heat setting temperature measured by differential scanning calorimetry (DSC) carried out on the biaxially oriented polyester film is 160° C. or higher, the biaxially oriented polyester film is provided with high crystallinity, and in a case of being used in the laminated polyester film, excellent weather resistance is provided. In a case where the above-mentioned small endothermic peak temperature is 210° C. or lower, the biaxially oriented polyester film is a polyester film provided with aligned molecular orientation. Therefore, in a case of being used in the laminated polyester film, excellent weather resistance is achieved.

The small endothermic peak temperature of the biaxially oriented polyester film derived from the heat setting temperature measured by DSC is preferably 170° C. or higher and 200° C. or lower, and more preferably 180° C. or higher and 190° C. or lower. When the small endothermic peak temperature is in the above-described range, in a case of being used in the laminated polyester film, the laminated polyester film is provided with better weather resistance.

The small endothermic peak temperature is measured in the following method.

The small endothermic peak temperature is measured by using a differential scanning calorimeter “Robot DSC-RDC 220” manufactured by Seiko Instruments Inc., on the basis of JIS K 7122:1987 (refer to JIS Handbook 1999). For data analysis, a disk station “SSC/5200” is used.

Specifically, the small endothermic peak temperature is measured by weighing 5 mg of the biaxially oriented polyester film on a sample pan and increasing the temperature from 25° C. to 300° C. at a rate of temperature rise of 20° C./min.

The small endothermic peak temperature is determined by reading the temperature of a fine endothermic peak before a crystallization/melting peak (on a lower temperature side than the crystallization/melting peak) from a differential scanning calorimetry chart obtained by the measurement. In a case where it is difficult to observe a fine endothermic peak, a region surrounding the crystallization/melting peak in the chart is enlarged, and a fine endothermic peak is read.

A method of reading the fine endothermic peak is performed on the basis of the following description.

First, straight lines are drawn at a value at 135° C. and at a value at 155° C. to be parallel to a Y axis in the differential scanning calorimetry chart, and a baseline is drawn. A endothermic side area enclosed by a curve in a graph, the two straight lines parallel to the Y axis described above, and the baseline is obtained. In same manner, areas for 17 points of 140° C. and 160° C., 145° C. and 165° C., 150° C. and 170° C., 155° C. and 175° C., 160° C. and 180° C., 165° C. and 185° C., 170° C. and 190° C., 175° C. and 195° C., 180° C. and 200° C., 185° C. and 205° C., 190° C. and 210° C., 195° C. and 215° C., 200° C. and 220° C., 205° C. and 225° C., 210° C. and 230° C., 215° C. and 235° C., and 220° C. and 240° C. are obtained. Since the amount of absorbed heat of a small endothermic peak is typically 0.2 J/g or higher and 5.0 J/g or lower, data only with an area of 0.2 J/g or higher and 5.0 J/g or lower is treated as effective data. Among a total of 18 pieces of area data, the peak temperature of an endothermic peak in a temperature region of data which is effective data and has the largest area is referred to as a small endothermic peak temperature. In a case where there is no effective data, it is assumed that there is no small endothermic peak temperature.

In addition, the above-described small endothermic peak temperature can be controlled by the treatment temperature (heat setting temperature) in the heat setting process, which will be described later.

(Polyester)

The biaxially oriented polyester film includes a polyester. The kind of the polyester is not particularly limited, and well-known polyesters may be selected.

Examples of the polyester include a linear saturated polyester synthesized from an aromatic dibasic acid or an ester-forming derivative of an aromatic dibasic acid and a diol or an ester-forming derivative of a diol. Specific examples of the linear saturated polyester include polyethylene terephthalate, polyethylene isophthalate, polybutylene terephthalate, poly(1,4-cyclohexylene dimethylene terephthalate), and polyethylene-2,6-naphthalate. Among these, in terms of the balance between mechanical properties and costs, polyethylene terephthalate, polyethylene-2,6-naphthalate, and poly(1,4-cyclohexylene dimethylene terephthalate) are particularly preferable.

The polyester may be a homopolymer or a copolymer. Furthermore, the polyester may also include a small amount of another kind of resin (for example, polyimide).

The kind of the polyester is not limited to the above-described polyester, and a well-known polyester may also be used. As the well-known polyester, a polyester may be synthesized by using a dicarboxylic acid component and a diol component. Otherwise, a commercially available polyester may also be used.

In a case where a polyester is synthesized, the polyester can be obtained by, for example, a method of causing a (a) dicarboxylic acid component and a (b) diol component to undergo at least one of an esterification reaction or a transesterification reaction according to a well-known method.

Examples of the (a) dicarboxylic acid component include dicarboxylic acids or ester derivatives of dicarboxylic acids including: aliphatic dicarboxylic acids such as malonic acid, succinic acid, glutaric acid, adipic acid, suberic acid, sebacic acid, dodecanedioic acid, dimer acid, eicosanedioic acid, pimelic acid, azelaic acid, methylmalonic acid, and ethylmalonic acid; alicyclic dicarboxylic acids such as adamantane dicarboxylic acid, norbornene dicarboxylic acid, cyclohexane dicarboxylic acid, and decalin dicarboxylic acid; and aromatic dicarboxylic acids such as terephthalic acid, isophthalic acid, phthalic acid, 1,4-naphthalene dicarboxylic acid, 1,5-naphthalene dicarboxylic acid, 2,6-naphthalene dicarboxylic acid, 1,8-naphthalene dicarboxylic acid, 4,4′-diphenyl dicarboxylic acid, 4,4′-diphenyl ether dicarboxylic acid, 5-sodium sulfoisophthalic acid, phenylindane dicarboxylic acid, anthracene dicarboxylic acid, phenanthrene dicarboxylic acid, and 9,9′-bis(4-carboxyphenyl) fluorene acid.

Examples of the (b) diol component include diol compounds including: aliphatic diols such as ethylene glycol, 1,2-propanediol, 1,3-propanediol, 1,4-butanediol, 1,2-butanediol, and 1,3-butanediol; alicyclic diols such as cyclohexane dimethanol, spiroglycol, and isosorbide; and aromatic diols such as bisphenol A, 1,3-benzenedimethanol, 1,4-benzenedimethanol, and 9,9′-bis(4-hydroxyphenyl)fluorene.

As the (a) dicarboxylic acid component, at least one kind of the aromatic dicarboxylic acids is preferably used. More preferably, an aromatic dicarboxylic acid is included as a primary component in the dicarboxylic acid component. In addition, the “primary component” means that the proportion of the aromatic dicarboxylic acid in the dicarboxylic acid component is 80 mass % or more. As the (a) dicarboxylic acid component, a dicarboxylic acid component other than the aromatic dicarboxylic acid may be included. As the dicarboxylic acid component, an ester derivative of an aromatic dicarboxylic acid or the like is used.

As the (b) diol component, at least one kind of the aliphatic diols is preferably used. As the aliphatic diol, ethylene glycol may be included, and ethylene glycol is preferably included as a primary component. In addition, the “primary component” means that the proportion of the ethylene glycol to the diol component is 80 mass % or more.

The amount of the aliphatic diol (for example, ethylene glycol) used is preferably in a range of 1.015 mol to 1.50 mol with respect to 1 mol of the aromatic dicarboxylic acid (for example, terephthalic acid) and, as necessary, an ester derivative of the aromatic dicarboxylic acid. The amount of the aliphatic diol used is more preferably in a range of 1.02 mol to 1.30 mol, and even more preferably in a range of 1.025 mol to 1.10 mol. When the amount of the aliphatic diol used is in a range of 1.015 mol or more, the esterification reaction favorably proceeds, and when the amount of the aliphatic diol used is in a range of 1.50 mol or less, for example, the generation of diethylene glycol as a byproduct due to the dimerization of ethylene glycol is suppressed, and characteristics of the polyester, such as melting point, glass transition temperature, crystallinity, heat resistance, hydrolysis resistance, and weather resistance can be favorably maintained.

In the esterification reaction or the ester exchange reaction, a well-known reaction catalyst may be used. Examples of the reaction catalyst include alkali metal compounds, alkaline-earth metal compounds, zinc compounds, lead compounds, manganese compounds, cobalt compounds, aluminum compounds, antimony compounds, titanium compounds, and phosphorus compounds. Typically, the reaction catalyst is added in an arbitrary stage before the completion of the esterification reaction or the ester exchange reaction of the polyester. As the reaction catalyst, antimony compounds, germanium compounds, and titanium compounds are preferable.

For example, in a case where a germanium compound is used as the reaction catalyst, powder of a germanium compound is preferably used as it is.

For example, in the esterification reaction, the aromatic dicarboxylic acid and the aliphatic diol are polymerized in the presence of a reaction catalyst including a titanium compound. In this esterification reaction, as the titanium compound which serves as the reaction catalyst, an organic chelate titanium complex having an organic acid as a ligand may be used, and a process for adding at least the organic chelate titanium complex, a magnesium compound, and a pentavalent phosphoric acid ester with no aromatic ring as a substituent in this order during the reaction may be performed.

Specifically, in the esterification reaction, first, the aromatic dicarboxylic acid and the aliphatic diol are mixed with a reaction catalyst including the organic chelate titanium complex, which is a titanium compound. The titanium compound such as the organic chelate titanium complex has a strong catalytic activity for the esterification reaction and is thus capable of promoting the progress of the esterification reaction. At this time, the titanium compound may be added after the aromatic dicarboxylic acid component and the aliphatic diol component are mixed together, or the aliphatic diol component (or the aromatic dicarboxylic acid component) may be mixed after the aromatic dicarboxylic acid component (or the aliphatic diol component) and the titanium compound are mixed together. Otherwise, the aromatic dicarboxylic acid component, the aliphatic diol component, and the titanium compound may be mixed together at the same time. A mixing method is not particularly limited, and a well-known method may be selected.

When the polyester is synthesized, it is preferable that a pentavalent phosphorus compound, which will be described below, is added as an additive.

As the pentavalent phosphorus compound, at least one pentavalent phosphoric acid ester not having an aromatic ring as a substituent is employed. As the pentavalent phosphorus compound, a phosphoric acid ester [(OR)₃—P═O; R is an alkyl group having 1 or 2 carbon atoms] having a lower alkyl group having 2 or less carbon atoms as a substituent is preferable, and trimethyl phosphate and triethyl phosphate are more preferable.

The amount of the phosphorus compound added is preferably in a range of 50 ppm to 90 ppm in terms of the phosphorus (P) element-equivalent value. The amount of the phosphorus compound is more preferably 60 ppm to 80 ppm, and even more preferably 60 ppm to 75 ppm.

In addition, when the polyester is synthesized, it is preferable that a magnesium compound is added as an additive.

When the polyester includes the magnesium compound, the electrostatic application property of the polyester improves.

Examples of the magnesium compound include magnesium salts such as magnesium oxide, magnesium hydroxide, magnesium alkoxide, magnesium acetate, magnesium carbonate. Among these, from the viewpoint of solubility in ethylene glycol, magnesium acetate is preferable.

In order to impart a high electrostatic application property, the amount of the magnesium compound added is preferably 50 ppm or more in terms of the magnesium (Mg) element-equivalent value with respect to the polyester after synthesis, and is more preferably in a range of 50 ppm to 100 ppm. The amount of the magnesium compound added is preferably in a range of 60 ppm to 90 ppm and more preferably in a range of 70 ppm to 80 ppm in terms of imparting the electrostatic application property.

In the esterification reaction, it is preferable that the polyester is synthesized (preferably subjected to melt polymerization) by adding the titanium compound as the reaction catalyst and the magnesium compound and the phosphorus compound as the additives so that a value Z calculated from the following expression (i) satisfies the following relational expression (ii). Here, the phosphorus (P) content refers to the amount of phosphorus derived from all phosphorus compounds including the pentavalent phosphoric acid ester with no aromatic ring, and the titanium (Ti) content refers to the amount of titanium derived from all titanium compounds including the organic chelate titanium complex.

As described above, in the esterification reaction, by using both the magnesium compound and the phosphorus compound in a system including a titanium compound and controlling the addition timings and addition proportions of the magnesium compound and the phosphorus compound, a polyester with a slight yellow tint tone can be obtained while appropriately maintaining the catalytic activity of the titanium compound at a high level. That is, by causing the esterification reaction to occur in the above-described method, a polyester, to which heat resistance is imparted so as not to cause yellow coloration to easily occur even when the polyester is exposed to a high temperature during the esterification reaction or subsequent film formation (for example, during melting), can be obtained.

Z=5×(P content [ppm]/atomic weight of P)−2×(Mg content [ppm]/atomic weight of Mg)−4×(Ti content [ppm]/atomic weight of Ti) (i)

0≦Z≦5.0 (ii)

The phosphorus compound does not only act on the titanium compound but also acts on the magnesium compound, and thus the above expression (i) serves as an index for quantitatively expressing the balance between the three.

Expression (i) represents the amount of phosphorus capable of acting on the titanium compound by subtracting the total amount of phosphorus that can react. It can be said that, in a case where the Z value is a positive value, the amount of phosphorus acting on the titanium compound is in an excessive state, and, conversely, in a case where the Z value is a negative value, the amount of phosphorus necessary to act on the titanium compound is in an insufficient state. In the reaction, since a Ti atom, a Mg atom, and a P atom do not have equal valences, weighting is carried out by multiplying the mole numbers of the respective atoms in Expression (i) by the valency numbers.

Meanwhile, by using a titanium compound which is inexpensive and can be easily procured, and the phosphorus compound and the magnesium compound which are described above, for the synthesis of the polyester, a polyester having a reaction activity required for the reaction and excellent heat resistance can be obtained.

In Expression (ii), from the viewpoint of further improving the heat resistance of the polyester in a state of maintaining the polymerization reactivity, it is preferable to satisfy 1.0≦Z≦4.0 and it is more preferable to satisfy 1.5≦Z≦3.0.

As a suitable aspect of the esterification reaction, 1 ppm to 30 ppm of a chelate titanium complex having citric acid or citrate as a ligand may be added to the aromatic dicarboxylic acid and the aliphatic diol before the completion of the esterification reaction. Thereafter, it is preferable to add 60 ppm to 90 ppm (more preferably 70 ppm to 80 ppm) of a weakly acidic magnesium salt in the presence of the chelate titanium complex and after the above-described addition, further add 60 ppm to 80 ppm (more preferably 65 ppm to 75 ppm) of the pentavalent phosphoric acid ester with no aromatic ring as a substituent.

The esterification reaction may be caused while removing water or alcohols generated due to the reaction to be discharged to the outside of the system using a multi-stage apparatus including at least two reactors connected in series, under a condition in which ethylene glycol is refluxed.

The esterification reaction may be caused a single stage or may be caused in multiple separated stages.

In a case where the esterification reaction is caused in a single stage, the temperature of the esterification reaction is preferably 230° C. to 260° C. and more preferably 240° C. to 250° C.

In a case where the esterification reaction is caused in multiple separated stages, the temperature of the esterification reaction in a first reactor is preferably 230° C. to 260° C. and more preferably 240° C. to 250° C., and the pressure in the reactor is preferably 1.0 kg/cm² to 5.0 kg/cm², and more preferably 2.0 kg/cm² to 3.0 kg/cm². The temperature of the esterification reaction in a second reactor is preferably 230° C. to 260° C., and more preferably 245° C. to 255° C., and the pressure in the reactor is preferably 0.5 kg/cm² to 5.0 kg/cm², and more preferably 1.0 kg/cm² to 3.0 kg/cm². Furthermore, in a case where the esterification reaction is caused in three or more separated stages, conditions for the esterification reaction in an intermediate stage are set to conditions between those in a first reactor and those in a final reactor.

Meanwhile, a polycondensation reaction of an esterification reaction product generated in the esterification reaction is caused so as to generate a polycondensate. The polycondensation reaction may be caused in a single stage or may be caused in multiple separated stages.

The esterification reaction product such as an oligomer generated in the esterification reaction is subsequently subjected to a polycondensation reaction. This polycondensation reaction can be suitably caused by supplying the esterification reaction product to a multi-stage polycondensation reactor.

For example, as for conditions of the polycondensation reaction in a case where the polycondensation reaction is carried out in reactors in three stages, the following conditions are preferable.

An aspect of the first reactor, in which the reaction temperature is 255° C. to 280° C. and more preferably 265° C. to 275° C., and the pressure in the first reactor is 100 torr to 10 torr (13.3×10⁻³ MPa to 1.3×10⁻³ MPa) and more preferably 50 torr to 20 torr (6.67×10⁻³ MPa to 2.67×10⁻³ MPa), is preferable.

An aspect of the second reactor, in which the reaction temperature is 265° C. to 285° C. and more preferably 270° C. to 280° C., and the pressure in the second reactor is 20 torr to 1 torr (2.67×10⁻³ MPa to 1.33×10⁻⁴ MPa) and more preferably 10 torr to 3 torr (1.33×10⁻³ MPa to 4.0×10⁻⁴ MPa), is preferable.

An aspect of the third reactor, which is the final reactor, in which the reaction temperature is 275° C. to 290° C. and more preferably 270° C. to 285° C., and the pressure is 10 torr to 0.1 torr (1.33×10⁻³ MPa to 1.33×10⁻⁵ MPa) and more preferably 5 torr to 0.5 torr (6.67×10⁻⁴ MPa to 6.67×10⁻⁵ MPa), is preferable.

The polyester synthesized as described above may further include additives such as a light stabilizer, an antioxidant, an ultraviolet absorber, a flame retardant, a lubricant (fine particles), a nucleating agent (crystallization agent), and a crystallization inhibitor.

After the polyester is polymerized by the esterification reaction, it is preferable to carry out solid-phase polymerization. When the polyester undergoes solid-phase polymerization, the moisture content of the polyester, the degree of crystallization, the acid value of the polyester, that is, the concentration (AV) of a terminal carboxyl group (COOH group) of the polyester, and the inherent viscosity.

Particularly, when the solid-phase polymerization is carried out, the concentration of ethylene glycol (EG) gas at the initiation of the solid-phase polymerization is set to be higher than the concentration of the EG gas at the end of the solid-phase polymerization, preferably in a range of 200 ppm to 1000 ppm, more preferably 250 ppm to 800 ppm, and even more preferably in a range of 300 ppm to 700 ppm. At this time, AV can be controlled by adding the average EG gas concentration (the average of the gas concentrations at the initiation and at the end of the solid-phase polymerization). That is, due to the addition of EG, a terminal hydroxyl group and a terminal COOH of EG group react with each other, whereby AV can be reduced. The difference between the EG gas concentration at the initiation of the solid-phase polymerization and the EG gas concentration at the end of the solid-phase polymerization is preferably 100 ppm to 500 ppm, more preferably 150 ppm to 450 ppm, and even more preferably 200 ppm to 400 ppm.

In addition, the temperature of the solid-phase polymerization is preferably 180° C. to 230° C., more preferably 190° C. to 215° C., and even more preferably 195° C. to 209° C.

In addition, the solid-phase polymerization time is preferably 10 hours to 40 hours, more preferably 14 hours to 35 hours, and even more preferably 18 hours to 30 hours.

Here, the polyester preferably has strong hydrolysis resistance. Therefore, the concentration of a terminal carboxyl group in the polyester is preferably 50 eq/t (here, ‘t’ represents ton, and ton means 1000 kg) or less, more preferably 35 eq/t or less, and even more preferably 20 eq/t or less. When the concentration of the terminal carboxyl group is 50 eq/t or less, hydrolysis resistance can be maintained and a decrease in strength can be suppressed during exposure to moisture and heat for a period of time. The lower limit of the concentration of the terminal carboxyl group is preferably 2 eq/t, and more preferably 3 eq/tin terms of maintaining the adhesiveness between the base material and an adjacent layer.

The concentration of the terminal carboxyl group in the polyester can be adjusted by the kind of a polymerization catalyst, film forming conditions (film forming temperature and time), solid-phase polymerization, and additives (a terminal sealing agent and the like).

—Carbodiimide Compound and Ketenimine Compound—

The polyester may include at least one of a carbodiimide compound or a ketenimine compound. The carbodiimide compound and the ketenimine compound may be used singly or in a combination of the two. Accordingly, deterioration of the polyester in a wet heat environment is prevented, which is effective in maintaining strong insulating properties even in the wet heat environment.

The carbodiimide compound or the ketenimine compound is included preferably in a ratio of 0.1 mass % to 10 mass % to the total mass of the polyester, more preferably in a proportion of 0.1 mass % to 4 mass %, and even more preferably in a proportion of 0.1 mass % to 2 mass %. When the content of the carbodiimide compound or the ketenimine compound is set in the above-described range, the adhesiveness between the base material and an adjacent layer can be enhanced. In addition, the heat resistance of the base material can be enhanced.

In a case where the carbodiimide compound and the ketenimine compound are used in combination, it is preferable that the sum of the contents of the two compounds is in the above-described range.

As the carbodiimide compound, a compound (including a polycarbodiimide compound) having one or more carbodiimide groups in a molecule may be employed.

Specifically, examples of a monocarbodiimide compound include dicyclohexylcarbodiimide, diisopropylcarbodiimide, dimethylcarbodiimide, diisobutylcarbodiimide, dioctylcarbodiimide, t-butylisopropylcarbodiimide, diphenylcarbodiimide, di-t-butylcarbodiimide, di-β-naphthylcarbodiimide, and N,N′-di-2, 6-diisopropylphenylcarbodiimide.

Examples of the polycarbodiimide compound include polycarbodiimide compounds in which the lower limit of the degree of polymerization is typically 2 or higher and preferably 4 or higher, and the upper limit of the degree of polymerization is typically 40 or lower and preferably 30 or lower. Specifically, as the polycarbodiimide compound, polycarbodiimide compounds produced using the methods described in the specification of U.S. Pat. No. 2,941,956A, JP1972-33279B (JP-S47-33279B), J. Org. Chem. Vol. 28, pp. 2069 to 2075 (1963), Chemical Review 1981, Vol. 81, Issue 4, pp. 619 to 621, and the like may be employed.

Examples of an organic diisocyanate, which is a raw material for producing the polycarbodiimide compound, include aromatic diisocyanates, aliphatic diisocyanates, alicyclic diisocyanates, and mixtures thereof. Specifically, the organic diisocyanate is exemplified by 1,5-naphthalene diisocyanate, 4,4′-diphenylmethane diisocyanate, 4,4′-diphenyldimethylmethane diisocyanate, 1,3-phenylene diisocyanate, 1,4-phenylene diisocyanate, 2,4-tolylene diisocyanate, 2,6-tolylene diisocyanate, a mixture of 2,4-tolylene diisocyanate and 2,6-tolylene diisocyanate, hexamethylene diisocyanate, cyclohexane-1,4-diisocyanate, xylylene diisocyanate, isophorone diisocyanate, 4,4′-dicyclohexylmethane diisocyanate, methylcyclohexane diisocyanate, tetramethylxylylene diisocyanate, 2, 6-diisopropylphenyl isocyanate, and 1,3,5-triisopropylbenzene-2,4-diisocyanate.

A specific polycarbodiimide compound that can be industrially procured is exemplified by CARBODILITE (registered trademark) HMV-8CA (manufactured by Nisshinbo Chemical Inc.), CARBODILITE (registered trademark) LA-1 (manufactured by Nisshinbo Chemical Inc.), STABAXOL (registered trademark) P (manufactured by Rhein Chemie Corporation), STABAXOL (registered trademark) P100 (manufactured by Rhein Chemie Corporation), STABAXOL (registered trade mark) P400 (Rhein Chemie Corporation), and STABILIZER 9000 (manufactured by RASCHIG GmbH).

The carbodiimide compound may be used singly, but a mixture of a plurality of the compounds may also be used.

As the ketenimine compound, a ketenimine compound represented by General Formula (K-A) shown below is preferably used.

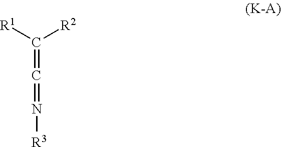

In General Formula (K-A), R¹ and R² each independently represent an alkyl group, an aryl group, an alkoxy group, an alkoxycarbonyl group, an aminocarbonyl group, an aryloxy group, an acyl group or an aryloxycarbonyl group, and R³ represents an alkyl group or an aryl group.

Here, the molecular weight of a portion excluding the nitrogen atom and the substituent R³ bonded to the nitrogen atom in the ketenimine compound is preferably 320 or more. That is, in General Formula (K-A), the molecular weight of a R¹—C(═C)—R² group is preferably 320 or more. The molecular weight of the portion excluding the nitrogen atom and the substituent R³ bonded to the nitrogen atom in the ketenimine compound is more preferably 500 to 1500 and even more preferably 600 to 1000. As described above, when the molecular weight of the portion excluding the nitrogen atom and the substituent R³ bonded to the nitrogen atom in the ketenimine compound is in the above-described range, the adhesiveness between the base material and an adjacent layer can be increased. This is because, when the portion excluding the nitrogen atom and the substituent R³ bonded to the nitrogen atom in the ketenimine compound has a certain range of molecular weight, the polyester terminal which is bulky to a certain extent diffuses into the layer adjacent to the base material, and an anchorage effect is exhibited.

The molar molecular weight of the ketenimine compound with respect to the number of ketenimine portions (>C═C═N—) in the ketenimine compound (the molar molecular weight/the number of ketenimine portions) is preferably 1000 or less, more preferably 500 or less, and even more preferably 400 or less. When the molecular weight of the substituent on carbon in the ketenimine portion of the ketenimine compound and the molar molecular weight of the ketenimine compound with respect to the number of the ketenimine portions are in the above-described ranges, the sublimation of the ketenimine compound itself is suppressed, the sublimation of the ketene compound generated when the terminal carboxyl group of the polyester is sealed is suppressed, and furthermore, the terminal carboxyl group of the polyester can be sealed with a small amount of the ketenimine compound added.

The ketenimine compound having at least one ketenimine group can be synthesized with reference to the method described in, for example, J. Am. Chem. Soc., 1953, 75(3), pp. 657 to 660.

[Undercoat Layer]

The laminated polyester film includes the undercoat layer which is formed by applying the undercoat layer forming composition onto one surface of the polyester film stretched in the first direction before being stretched in the second direction, and then stretching the resultant in the second direction, and has a modulus of elasticity of 0.7 GPa or higher.

(Modulus of Elasticity)

When the modulus of elasticity of the undercoat layer is 0.7 GPa or higher, the laminated polyester film has excellent cohesive fracture resistance.

The modulus of elasticity of the undercoat layer is preferably 1.0 GPa or higher and more preferably 1.3 GPa or higher.

The modulus of elasticity of the undercoat layer is preferably 2.0 GPa or lower and more preferably 1.7 GPa or lower.

When the modulus of elasticity of the undercoat layer is in the above-described range, in a case of being used in a laminated film, cohesive fracture resistance is further improved.

The modulus of elasticity of the undercoat layer can be adjusted by the kind of a resin component included in the undercoat layer, and in a case where a crosslinking agent is included, can also be adjusted by the kind of the crosslinking agent or the amount thereof added.

The modulus of elasticity of the undercoat layer can be measured in the following method.

First, the undercoat layer forming composition is applied to a polyethylene terephthalate (PET) film (CERAPEEL (registered trademark) manufactured by Toray Industries, Inc.) treated by a peeling agent so as to cause the film thickness thereof after being dried to reach 15 μm and is dried at 170° C. for two minutes, thereby forming an undercoat layer on the PET film.

The undercoat layer is cut into a size of 3 cm×5 mm, and the undercoat layer is peeled away from the PET film.

A tensile test for the undercoat layer is carried out on the obtained undercoat layer using a tensile tester (TENSILON manufactured by A&D Company) in an environment with a temperature of 23.0° C. and a relative humidity of 50.0% at a rate of 50 mm/min, and the modulus of elasticity thereof is measured.

(Inline Coating Method)

The undercoat layer is formed by applying the undercoat layer forming composition onto one surface of the polyester film stretched in the first direction before, and stretching the polyester film, to which the undercoat layer forming composition is applied, in the second direction perpendicular to the first direction along the film surface. That is, the undercoat layer is formed by a so-called inline coating method, which is distinguished from an offline coating method in which a film is wound during the production of a laminated polyester film and coating is separately carried out.

When the undercoat layer is formed by the inline coating method, the adhesiveness between the layers of the laminated polyester film is improved, and this is advantageous in terms of productivity.

The thickness of the undercoat layer is preferably 0.01 μm to 1 μm. The thickness of the undercoat layer is preferably 0.01 μm or greater, more preferably 0.03 μm or greater, and even more preferably 0.05 μm or greater. In addition, the thickness of the undercoat layer is preferably 1 μm or smaller, more preferably 0.8 μm or smaller, and even more preferably 0.7 μm or smaller.

(Undercoat Layer Forming Composition)

The undercoat layer is formed by applying, as the undercoat layer forming composition, a solution in which a resin component described below is dissolved in an appropriate solvent, or a dispersion in which the resin component is dispersed in a dispersion medium, onto the polyester film stretched in the first direction, and stretching the resultant in the second direction perpendicular to the first direction along the film surface. In addition to the resin component and the solvent or the dispersion medium, other additives may be included in the undercoat layer forming composition as necessary. In consideration of environmental load, the aqueous dispersion dispersed in water is preferably used in the undercoat layer forming composition.

In the embodiment of the present invention, a method for obtaining the aqueous dispersion is not particularly limited. Examples of the method for obtaining the aqueous dispersion include, as exemplified in JP2003-119328A, a method of heating and stirring a resin component, water, and an organic solvent as necessary, preferably in a sealable container. In this method, the resin component can be appropriately formed in an aqueous dispersion even though a non-volatile auxiliary agent for making an aqueous dispersion is not actually added thereto. Therefore, the method is preferable as the method for forming the aqueous dispersion.

The solid content of the resin component in the aqueous dispersion is not particularly limited, but from the viewpoint of ease of coating and case of adjustment of the thickness of the undercoat layer, is preferably 1 mass % to 60 mass %, more preferably 2 mass % to 50 mass %, and even more preferably 5 mass % to 30 mass % with respect to the total mass of the aqueous dispersion.

—Resin Component—

The resin component included in the undercoat layer can form a layer through the inline coating method, and is not particularly limited as long as a modulus of elasticity of 0.7 GPa or higher is achieved in a case where the resin component is included in the undercoat layer. Examples of the resin component included in the undercoat layer include an acrylic resin, a polyester resin, a polyolefin resin, and a silicone-based compound.

The undercoat layer includes an acrylic resin, and the content of the acrylic resin in the resin component included in the undercoat layer is preferably 50 mass % or more and more preferably 75 mass % or more.

When 50 mass % or more of the resin component is the acrylic resin, the modulus of elasticity of the undercoat layer can be easily adjusted to be 0.7 GPa or higher, and in a case of being used in a laminated film, cohesive fracture resistance is further improved.

˜Acrylic Resin˜

As the acrylic resin, for example, a polymer including polymethyl methacrylate, polyethyl acrylate, or polybutyl methacrylate is preferable.

As the acrylic resin, a commercially available product which is released may be used. Examples thereof include AS-563A (manufactured by Daicel FineChem Ltd.), and JURYMER (registered trademark) ET-410 and JURYMER SEK-301 (both manufactured by Toagosei Co., Ltd.).

As the acrylic resin, from the viewpoint of modulus of elasticity in a case of being used in the undercoat layer, an acrylic resin including polymethyl methacrylate or polyethyl acrylate is more preferable, and an acrylic resin including a styrene skeleton is even more preferable.

˜Polyester Resin˜

As the polyester resin, for example, polyethylene terephthalate (PET), or polyethylene-2,6-naphthalate (PEN) is preferable.

As the polyester resin, a commercially available product which is released may be used. For example, VYLONAL (registered trademark) MD-1245 (manufactured by Toyobo Co., Ltd.) may be preferably used.

˜Polyurethane Resin˜

As a polyurethane resin, for example, a carbonate-based urethane resin is preferable. For example, SUPERFLEX (registered trademark) 460 (manufactured by DKS Co. Ltd.) may be preferably used.

˜Polyolefin Resin˜

As the polyolefin resin, for example, a modified polyolefin copolymer is preferable. As the polyolefin resin, a commercially available product which is released may be used. Examples thereof include ELEVES (registered trademark) SE-1013N, SD-1010, TC-4010, TD-4010 (all manufactured by Unitika Ltd.), HITECH 53148, 53121, 58512 (all manufactured by TOHO CHEMICAL INDUSTRY Co., Ltd.), and CHEMIPEARL (registered trademark) S-120, S-75N, V100, and EV210H (all manufactured by Mitsui chemicals, Inc.). Among these, it is preferable to use ELEVES (registered trademark) SE-1013N (manufactured by Unitika Ltd.), which is a terpolymer of low-density polyethylene, acrylic acid ester, and maleic anhydride, in terms of adhesion enhancement.

In addition, an acid-modified polyolefin resin described in paragraphs [0022] to of JP2014-76632A may be preferably used.

˜Silicone-Based Compound˜

As the silicone-based compound, a compound having a (poly)siloxane structural unit, which will be described later, is preferable. As the silicone-based compound, a commercially available product which is released may be used. Examples thereof include CERANATE (registered trademark) WSA1060 and CERANATE WSA1070 (both manufactured by DIC Corporation), and H7620, H7630, and H7650 (all manufactured by Asahi Kasei Corporation).

˜Other Additives˜

Examples of other additives include a crosslinking agent for improving film strength, a surfactant for improving coating film uniformity, an antioxidant, and a preservative selected depending on a function to be imparted to the undercoat layer.

˜Crosslinking Agent˜

The undercoat layer forming composition preferably includes a crosslinking agent.

When the undercoat layer forming composition includes a crosslinking agent, a crosslinking structure is formed in the resin component included in the undercoat layer forming composition, and a layer having further-improved adhesiveness and film strength is formed.

That is, since an undercoat layer formed by using the undercoat layer forming composition including the crosslinking agent includes the crosslinking agent, excellent adhesiveness to an adjacent layer and film strength are obtained.

As the crosslinking agent, an epoxy-based crosslinking agent, an isocyanate-based crosslinking agent, a melamine-based crosslinking agent, a carbodiimide-based crosslinking agent, an oxazoline-based crosslinking agent, and the like may be employed. From the viewpoint of ensuring adhesiveness between the undercoat layer and the base material after exposure to moisture and heat for a period of time, an oxazoline-based crosslinking agent among these is particularly preferable.

That is, the undercoat layer preferably includes the oxazoline-based crosslinking agent.

Specific examples of the oxazoline-based crosslinking agent include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, 2,2′-bis-(2-oxazoline), 2,2′-methylene-bis-(2-oxazoline), 2,2′-ethylene-bis-(2-oxazoline), 2,2′-trimethylene-bis-(2-oxazoline), 2,2′-tetramethylene-bis-(2-oxazoline), 2,2′-hexamethyl ene-bis-(2-oxazoline), 2,2′-octamethylene-bis-(2-oxazoline), 2,2′-ethylene-bis-(4,4′-dimethyl-2-oxazoline), 2,2′-p-phenyl ene-bis-(2-oxazoline), 2,2′-m-phenylene-bis-(2-oxazoline), 2,2′-m-phenylene-bis-(4,4′-dimethyl-2-oxazoline), bis-(2-oxazolinylcyclohexane)sulfide, and bis-(2-oxazolinylnorbornane)sulfide. Furthermore, (co)polymers of these compounds may also be preferably used.

As the oxazoline-based crosslinking agent, a commercially available product which is released may be used. For example, EPOCROS (registered trademark) K2010E, K2020E, K2030E, WS500, and WS700 (all manufactured by Nippon Shokubai Co., Ltd.) may be used.

As the crosslinking agent, only one kind of crosslinking agent may be used, or a combination of two or more kinds of crosslinking agent may be used.

The amount of the crosslinking agent added is preferably in a range of 1 parts by mass to 30 parts by mass with respect to 100 parts by mass of the resin component, and is more preferably in a range of 5 parts by mass to 25 parts by mass.

˜Catalyst for Crosslinking Agent˜

In the undercoat layer forming composition, the crosslinking agent and a catalyst for the crosslinking agent may be used in combination. When the undercoat layer forming composition includes the catalyst for the crosslinking agent, a crosslinking reaction between the resin component and the crosslinking agent is accelerated, and the solvent resistance of the undercoat layer is improved. In addition, as the crosslinking reaction favorably proceeds, the film strength and dimensional stability of the undercoat layer can be further improved.

Particularly, in a case where a crosslinking agent having an oxazoline group (oxazoline-based crosslinking agent) is used as the crosslinking agent, a catalyst for the crosslinking agent may be used.

Examples of the catalyst for the crosslinking agent include onium compounds.

As the onium compounds, ammonium salts, sulfonium salts, oxonium salts, iodonium salts, phosphonium salts, nitronium salts, nitrosonium salts, diazonium salts, and the like may be suitably employed.

Specific examples of the onium compound include: ammonium salts such as ammonium monophosphate, ammonium diphosphate, ammonium chloride, ammonium sulfate, ammonium nitrate, ammonium p-toluenesulfonate, ammonium sulfamate, ammonium imidodisulfonate, tetrabutylammonium chloride, benzyltrimethylammonium chloride, triethylbenzyl ammonium chloride, tetrabutyl ammonium tetrafluoroborate, tetrabutyl ammonium hexafluorophosphate, tetrabutylammonium perchlorate, and tetrabutylammonium sulfate;

sulfonium salts such as trimethylsulfonium iodide, trimethylsulfonium tetrafluoroborate, diphenylmethylsulfonium tetrafluoroborate, benzyltetramethylenesulfonium tetrafluoroborate, 2-butenyltetramethylenesulfonium hexafluoroantimonate, and 3-methyl-2-butenyltetramethylenesulfonium hexafluoroantimonate;

oxonium salts such as trimethyloxonium tetrafluoroborate;

iodonium salts such as diphenyliodonium chloride and diphenyliodonium tetrafluoroborate;

phosphonium salts such as cyanomethyltributylphosphonium hexafluoroantimonate and ethoxycarbonylmethyltributylphosphonium tetrafluoroborate;

nitronium salts such as nitronium tetrafluoroborate;

nitrosonium salts such as nitrosonium tetrafluoroborate; and

diazonium salts such as 4-methoxybenzenediazonium chloride.

Among these, in terms of shortening the curing time, the onium compounds are more preferably the ammonium salts, the sulfonium salts, the iodonium salts, and the phosphonium salts and the ammonium salts are even more preferable. From the viewpoint of safety, pH, and costs, phosphoric acid-based onium compounds and benzyl chloride-based onium compounds are preferable. The onium compound is particularly preferably ammonium diphosphate.

As the catalyst for the crosslinking agent, only one kind of catalyst may be used, and a combination of two or more kinds of catalyst may be used.

The amount of the catalyst for the crosslinking agent added is preferably, with respect to the crosslinking agent in the undercoat layer forming composition, in a range of 0.1 mass % to 15 mass %, more preferably in a range of 0.5 mass % to 12 mass %, even more preferably in a range of 1 mass % to 10 mass %, and particularly preferably 2 mass % to 7 mass %. An added amount of the catalyst for the crosslinking agent of 0.1 mass % or more with respect to the crosslinking agent means that the catalyst for the crosslinking agent is actively included. Due to the catalyst for the crosslinking agent included in the undercoat layer forming composition, a crosslinking reaction between the resin component and the crosslinking agent more favorably proceeds, and superior solvent resistance is obtained. In addition, when the content of the catalyst for the crosslinking agent is 15 mass % or less, there is an advantage in terms of solubility, filterability of a coating liquid, and adhesiveness between layers adjacent to each other.

In order to enhance productivity in the inline coating method of the undercoat layer, that is, a film forming speed, the aqueous dispersion may include a non-volatile auxiliary agent for making an aqueous dispersion such as a surfactant and an emulsifier. By selecting an appropriate non-volatile auxiliary agent for making an aqueous dispersion, both productivity and various performances can be more effectively achieved.

Here, the non-volatile auxiliary agent for making an aqueous dispersion means a non-volatile compound that contributes to dispersion and stabilization of the resin component. Examples of the non-volatile auxiliary agent for making an aqueous dispersion include a cationic surfactant, an anionic surfactant, a nonionic surfactant, an amphoteric surfactant, a fluorine-based surfactant, a reactive surfactant, and a water soluble polymer. The non-volatile auxiliary agent for making an aqueous dispersion also includes those generally used for emulsion polymerization, and emulsifiers. Particularly, a fluorine-based surfactant and a nonionic surfactant are preferred.

The fluorine-based surfactant and the nonionic surfactant are nonionic and do not function as a catalyst for decomposition of the polyester. Therefore, excellent weather resistance is achieved. The amount of the surfactant added is preferably, with respect to an aqueous coating liquid, 1 ppm to 100 ppm, more preferably 5 ppm to 70 ppm, and particularly preferably 10 ppm to 50 ppm.

[Production Method of Laminated Polyester Film]

A production method of the laminated polyester film includes: a process of stretching an un-stretched polyester film in a first direction; a process of applying an undercoat layer forming composition onto one surface of the polyester film stretched in the first direction; a process of forming an undercoat layer having a modulus of elasticity of 0.7 GPa or higher by stretching the polyester film, to which the undercoat layer forming composition is applied, in a second direction perpendicular to the first direction; and a heat setting process of carrying out a heat setting treatment on the polyester film in which the undercoat layer is formed, at 165° C. or higher and 215° C. or lower.

### (Process of Stretching Un-Stretched Polyester Film in First Direction)

The production method of the laminated polyester film includes the process of stretching the un-stretched polyester film in the first direction.

Regarding the un-stretched polyester film, for example, using the above-described polyester as a raw resin material, the raw resin material is dried and is thereafter melted. The obtained melt is caused to pass through a gear pump or a filter and is thereafter extruded through a die into a cooling roll to cool and solidify, thereby obtaining the un-stretched polyester film. The melting is carried out preferably using an extruder. As the extruder, a monoaxial extruder may be used or a biaxial extruder may be used.

The extrusion is preferably carried out in a vacuum or in an inert gas atmosphere. The temperature of the extruder is preferably the melting point of the polyester being used to the melting point+80° C. or lower, more preferably in a range of the melting point+10° C. to the melting point+70° C., and even more preferably in a range of the melting point+20° C. to the melting point+60° C. When the temperature of the extruder is the melting point+10° C. or higher, the polyester is sufficiently melted. On the other hand, when the temperature of the extruder is the melting point+70° C. or lower, decomposition of the polyester is suppressed, which is preferable. In addition, it is preferable to dry the polyester before being introduced into the extruder, and the moisture content of the polyester after the drying is preferably 10 ppm to 300 ppm and more preferably 20 ppm to 150 ppm.

For the purpose of improving the hydrolysis resistance of the un-stretched polyester film, at least one of a ketenimine compound or a carbodiimide compound may be added when the raw resin material is melted.

The carbodiimide compound or the ketenimine compound may be directly introduced into the extruder. However, it is preferable to form a masterbatch with the polyester in advance to be introduced into the extruder from the viewpoint of extrusion stability. In a case where the extrusion is carried out by using the masterbatch including the ketenimine compound, it is preferable to vary the supply amount of the masterbatch containing the including compound. Meanwhile, a concentrated ketenimine compound is preferably used for the masterbatch. The concentration ratio is preferably 2 times to 100 times the concentration in a film after film formation, and more preferably 5 times to 50 times from the viewpoint of costs.

The melt extruded from the extruder is caused to pass through a gear pump, a filter, and a multi-layer die and flow onto a casting drum. As the type of the multi-layer die, either a multi-manifold die or a feedblock die may be suitably used. The shape of the die may be any of a T die, a coat-hanger die, and a fishtail die. It is preferable to change the temperature at the tip end (die lip) of the die. On the casting drum, the melt may be caused to come into close contact with the cooling roll using an electrostatic application method. At this time, it is preferable to change the driving speed of the casting drum. The surface temperature of the casting drum may be set to approximately 10° C. to 40° C. The diameter of the casting drum is preferably 0.5 m or greater and 5 m or lower, and more preferably 1 m or greater and to 4 m or lower. The driving speed of the casting drum (the linear speed of the outermost circumference) is preferably 1 m/min or higher and 50 m/min or lower, and more preferably 3 m/min or higher and 30 m/min or lower.

In the production method of the laminated polyester film, the un-stretched polyester film which is formed is subjected to a stretching treatment. The stretching is preferably carried out in one direction a the machine direction (MD) and a transverse direction (TD). The stretching treatment may be either MD stretching or TD stretching.

The stretching treatment is carried out preferably at a temperature of the glass temperature (Tg: in the unit of ° C.) of the polyester film or higher and Tg+60° C. or lower, more preferably at a temperature of Tg+3° C. or higher and Tg+40° C. or lower, and even more preferably Tg+5° C. or higher and Tg+30° C. or lower. During the stretching treatment, it is preferable to impart a temperature distribution to the polyester film.

The stretching ratio during the stretching treatment is preferably 270% to 500%, more preferably 280% to 480%, and even more preferably 290% to 460%. The stretching ratio mentioned here is obtained using the following expression.

Stretching ratio (%)=100×{(length after stretching)/(length before stretching)}

The polyester film stretched in the first direction can be obtained through the following processes.

(Process of Applying Undercoat Layer Forming Composition)

The production method of the laminated polyester film includes the process the undercoat layer forming composition onto one surface of the polyester film stretched in the first direction.

The application process is preferable because a thin film with high uniformity can be simply formed. As an application method, for example, a well-known method using a gravure coater, a bar coater, or the like may be used. As a solvent for the undercoat layer forming composition used in the application process, water may be used, or an organic solvent such as toluene or methyl ethyl ketone may be used. As the solvent, one kind of solvent may be simply used, or a mixture of two or more kinds of solvent may be used.

The application of the undercoat layer forming composition onto the polyester film stretched in the first direction is carried out inline subsequent to the process of stretching the un-stretched polyester film in the first direction.

Before the application of the undercoat layer forming composition, it is also preferable to carry out a surface treatment such as a corona discharge treatment, a glow treatment, an atmospheric pressure plasma treatment, a flame treatment, or an UV treatment on the polyester film stretched in the first direction.

After the application of the undercoat layer forming composition, it is preferable to provide a process of drying the coating film. The drying process is a process of supplying dry air to the coating film. The average wind speed of the dry air is preferably 5 m/sec to 30 m/sec, more preferably 7 m/sec to 25 m/sec, and even more preferably 9 m/sec to 20 m/sec.

It is preferable that the drying of the coating film serves as a heat treatment.

(Process of Stretching Polyester Film in Second Direction)

The production method of the laminated polyester film includes at least the process of forming the undercoat layer having a modulus of elasticity of 0.7 GPa or higher by further stretching the polyester film to which the undercoat layer forming composition is applied (a polyester film in which the undercoat layer forming composition is applied onto the polyester film obtained by uniaxially stretching the un-stretched polyester film) in the second direction perpendicular to the first direction along the film surface.

As the polyester film is stretched in the second direction, the polyester film stretched in the first direction is stretched along with the undercoat layer forming composition, thereby obtaining a biaxially oriented polyester film coated with the undercoat layer.

The stretching may be carried out in either the machine direction (MD) or the transverse direction (TD) as long as the direction is perpendicular to the first direction.

A preferable aspect of the process of stretching the polyester film in the second direction is the same as the process of the stretching the un-stretched polyester film in the first direction.

(Heat Setting Process)

The production method of the laminated polyester film includes the heat setting process of carrying out the heat setting treatment on the polyester film in which the undercoat layer is formed, at 165° C. or higher and 215° C. or lower.

The heat setting process refers to a process of carrying out a heat treatment on the film at a temperature of 165° C. or higher and 215° C. or lower (preferably 175° C. or higher and 205° C. or lower, and more preferably 185° C. or higher and 190° C. or lower) for 1 second to 60 seconds (more preferably 2 seconds to 30 seconds). The heat setting temperature in the heat setting process determines a small endothermic peak temperature derived from the heat setting temperature measured by differential scanning calorimetry (DSC) of the biaxially oriented polyester film. That is, when the heat setting temperature is 165° C. or higher, the polyester film has high crystallinity and has excellent weather resistance in a case of being used in the laminated polyester film. In addition, when the heat setting temperature is 215° C. or lower, the polyester film is provided with aligned molecular orientation. Therefore, in a case of being used in the laminated polyester film, excellent weather resistance is achieved. The heat setting temperature mentioned here is a film surface temperature during the heat setting treatment.

In the heat setting process carried out after the stretching process, a portion of a volatile basic compound having a boiling point of 200° C. or lower may be caused to sublimate.

For example, in a case where the stretching in the second direction is transverse stretching, it is preferable that the heat setting process is carried out subsequent to the transverse stretching in a state where the polyester film is gripped by chucks in a tenter. At this time, the interval between the chucks may be the width at the time of the end of the transverse stretching. Otherwise, the interval may be widened, or the interval may be narrowed. When the heat setting process is carried out, fine crystals are generated, and mechanical characteristics or durability can be improved.

In the production method of the laminated polyester film, it is possible to carry out a thermal relaxation process subsequent to the heat setting process. The thermal relaxation process refers to a process of carrying out a treatment of contracting the biaxially oriented polyester film by applying heat to the biaxially oriented polyester film for stress relaxation. In the thermal relaxation process, relaxation is preferably carried out in at least one direction of the machine direction or the transverse direction. The relaxation ratio in both the machine direction and the transverse direction is preferably 1% to 15% (the ratio to the width after the transverse stretching), more preferably 2% to 10%, and even more preferably 3% to 8%. The relaxation temperature in the thermal relaxation process is preferably Tg of the polyester film+50° C. to Tg+180° C., more preferably Tg+60° C. to Tg+150° C., and even more preferably Tg+70° C. to Tg+140° C.

In the thermal relaxation process, in a case where the melting point of the biaxially oriented polyester film is referred to as Tm, the thermal relaxation treatment is carried out preferably at Tm−100° C. to Tm−10° C., more preferably Tm−80° C. to Tm−20° C., and even more preferably Tm−70° C. to Tm−35° C. Due to the thermal relaxation treatment in the thermal relaxation process, the generation of crystals in the biaxially oriented polyester film is accelerated, and mechanical strength and heat-shrinkable properties are improved. Furthermore, the hydrolysis resistance of the biaxially oriented polyester film is improved by the thermal relaxation treatment at Tm−35° C. or lower. This is because the reactivity with water is suppressed by increasing tension (binding) without disturbing the orientation of amorphous portions where hydrolysis easily occurs.

Relaxation in the transverse direction may be carried out by narrowing the width of clips of the tenter. In addition, relaxation in the machine direction may be carried out by narrowing the interval between adjacent clips of the tenter. As a method of narrowing the interval between the adjacent clips, a method of connecting the adjacent clips in a pantograph shape and narrowing the pantograph is employed. In addition, the biaxially oriented polyester film may be relaxed by being subjected to a heat treatment while being transported with low tension after being taken out of the tenter. The tension is preferably 0 N/mm² to 0.8 N/mm² per cross-sectional area of the biaxially oriented polyester film, more preferably 0 N/mm² to 0.6 N/mm², and even more preferably 0 N/mm² to 0.4 N/mm². A tension of 0 N/mm² can be realized by providing two or more pairs of nip rollers during transportation and loosening the film between the two or more pairs of nip rollers (in a suspended form).

Both ends of the biaxially oriented polyester film taken out of the tenter, which are gripped by the clips, are trimmed, and after both ends are subjected to knurling (press working), the film is preferably wound. The width of the biaxially oriented polyester film is preferably 0.8 m to 10 m, more preferably 1 m to 6 m, and even more preferably 1.5 m to 4 m. The thickness of the biaxially oriented polyester film is preferably 30 μm to 300 μm, more preferably 40 μm to 280 μm, and even more preferably 45 μm to 260 μm. The adjustment of the thickness of the biaxially oriented polyester film can be achieved by adjusting the discharge amount of the extruder, and adjusting the film forming speed (adjusting the speed of the cooling roll, the stretching speed connected thereto, and the like).

A film for recycling, such as the edge portion of the trimmed biaxially oriented polyester film, is recovered as a resin mixture and is recycled. The film for recycling becomes a raw material of a laminated polyester film for the next lot, and is returned to the drying process as described above such that the production processes are sequentially repeated.

<Solar Cell Protective Sheet>

The solar cell protective sheet has the laminated polyester film described above. Therefore, the solar cell protective sheet achieves both cohesive fracture resistance and weather resistance (wet heat stability).

The solar cell protective sheet may further have at least one functional layer such as a resin layer or a weather-resistant layer as necessary.

In the solar cell protective sheet, the laminated polyester film after being biaxially stretched may be coated with the following functional layer. For the coating of the functional layer, a well-known application technique such as a roll coating method, a knife edge coating method, a gravure coating method, and a curtain coating method may be used.

In addition, the laminated polyester film may be subjected to a surface treatment (a flame treatment, a corona treatment, a plasma treatment, an ultraviolet treatment, or the like) before being coated with such functional layers. Furthermore, it is also preferable that the laminated polyester film and the functional layers are attached to each other using a pressure sensitive adhesive.

[Resin Layer]

It is preferable that the solar cell protective sheet has the above-described laminated polyester film, and a resin layer including an acrylic resin disposed on the undercoat layer of the laminated polyester film.

The resin layer may have a single layer structure or a laminated structure made up of two or more layers. In a case where the resin layer has the laminated structure made up of two or more layers, for example, a resin layer (B) and a resin layer (C), which will be described below, are preferably included.

(Resin Layer (B))

It is more preferable that in the solar cell protective sheet, the resin layer (B) is further laminated on the surface on which the undercoat layer of the laminated polyester film is laminated.

As a lamination method of the resin layer (B), an aspect in which a solution in which a resin component in the resin layer (B) is dissolved in an appropriate solvent or a dispersion in which the resin component is dispersed in water is applied as a resin layer (B) forming composition so as to be laminated, is preferable.

As the resin component in the resin layer (B), it is preferable to include at least an acrylic resin, and the acrylic resin and another resin such as a polyolefin resin, a polyurethane resin, or a polyester resin may be used in combination.

As the resin component in the resin layer (B), a commercially available product which is released may be used. Examples thereof include: acrylic resins such as AS-563A (manufactured by Daicel Finechem Ltd.), JURYMER (registered trademark) ET-410 and JURYMER SEK-301 (both manufactured by Toagosei Co., Ltd.), and BONRON (registered trademark) XPS001 and BONRON (registered trademark) XPS002 (both manufactured by Mitsui chemicals, Inc.); and polyolefin resins such as ELEVES (registered trademark) SE-1013N, SD-1010, TC-4010, and TD-4010 (all manufactured by Unitika Ltd.), HITECH S3148, 53121, and 58512 (all manufactured by TOHO CHEMICAL INDUSTRY Co., Ltd.), and CHEMIPEARL (registered trademark) S-120, S-75N, V100, and EV210H (all manufactured by Mitsui chemicals, Inc.)

As the resin component in the resin layer (B), only one kind of resin component may be used, or a mixture of two or more kinds of resin component may be used. However, it is preferable that the content of the acrylic resin in the total mass of the resin component in the resin layer (B) is 50 mass % or more.

In addition to the resin component and the solvent or the dispersion medium, other additives may be included in the resin layer (B) forming composition as necessary.

—Other Additives—

Examples of other additives include inorganic particles for improving film strength, a crosslinking agent, a surfactant for improving coating film uniformity, a colorant, an ultraviolet absorber, an antioxidant, a preservative, and the like selected depending on a function to be imparted to the resin layer (B).

—Inorganic Particles—

The resin layer (B) preferably includes inorganic particles. Examples of the inorganic particles include: silica particles such as colloidal silica; metal oxide particles such as titanium dioxide, aluminum oxide, zirconium oxide, magnesium oxide, and tin oxide; inorganic carbonate particles such as calcium carbonate and magnesium carbonate; metal compound particles such as barium sulfate; and black pigment particles such as carbon black. Among these, metal oxide particles and black pigment particles are preferable, and colloidal silica, titanium dioxide, aluminum oxide, zirconium oxide, and carbon black are more preferable. The metal oxide particles mentioned above are white particle and thus can be used as a white pigment.

The resin layer (B) may include only one kind of inorganic particles or may also include two or more kinds thereof. In a case where two or more kinds of inorganic particles are included, two or more white pigments may be used, two or more kinds of black pigments may be included, or both a white pigment and a black pigment may be included.

When a black pigment is used as the inorganic particles, the solar cell protective sheet can be provided with shielding properties.

In a solar cell, from the viewpoint of designability, wires for connection to power generation elements and the like are preferably invisible to the outside, and a solar cell protective sheet provided with high shielding properties is preferable.

In the related art, in order to improve the shielding properties of the solar cell protective sheet, carbon black which is a black pigment is directly added to the base material. However, when carbon black is directly added to the base material, there has been a problem in that the carbon black serves as a nucleus of crystallization of a polyester, resulting in an increase in the crystallization rate of the polyester, and a difficulty in film formation through stretching, or in a case where a film obtained using a polyester is placed in a wet heat atmosphere, the degree of crystallization of the film rapidly increases, resulting in embrittlement within a short period of time and deterioration in the wet heat resistance of the film.

Contrary to this, in the embodiment of the present invention, since a black pigment such as carbon black is added to the resin layer (B), in addition to an effect of improving designability and film strength, an effect of suppressing a reduction in the wet heat resistance of the biaxially oriented polyester film which is to be the base material is achieved. Furthermore, there is also an advantage that the solar cell protective sheet can be provided with higher shielding properties.

Colloidal silica which can be used in the resin layer (B) means an aspect in which particles primarily including a silicon oxide are present in a colloidal form using water, an alcohol, a diol, or the like, or a mixture thereof as a dispersion medium.

The volume average particle diameter of the colloidal silica is preferably several nm to 100 nm. The volume average particle diameter thereof can be measured from MICROTRAC FRA manufactured by Honeywell International, Inc.

The shape of the colloidal silica particle may be a spherical shape, or may be a shape in which spherical particles may be connected like beads.

As the colloidal silica, a commercially available product which is released may be used. Examples thereof include SNOWTEX (registered trademark) series manufactured by Nissan Chemical Industries, Ltd., CATALOID (registered trademark) S series manufactured by JGC C&C, LEVASIL series manufactured by Bayer AG Specific examples thereof include: SNOWTEX (registered trademark) ST-20, ST-30, ST-40, ST-C, ST-N, ST-20L, ST-O, ST-OL, ST-S, ST-XS, ST-XL, ST-YL, ST-ZL, ST-OZL, and ST-AK manufactured by Nissan Chemical Industries, Ltd., SNOWTEX (registered trademark) AK series, SNOWTEX (registered trademark) PS series, and SNOWTEX (registered trademark) UP series.

Carbon black used in the resin layer (B) is not particularly limited, and carbon black which is known as a black pigment may be appropriately selected and used.

In order to obtain a strong coloration strength with a small amount of carbon black, as the carbon black, carbon black particles are preferably used, carbon black particles having a volume average particle diameter of 1 μm or smaller are more preferably used, and carbon black particles having a volume average particle diameter of 0.1 μm to 0.8 μm are even more preferably used. The volume average particle diameter can be measured by the above-described method.

In addition, carbon black particles are preferably used after being dispersed in water together with a dispersant.

As the carbon black, a commercially available product which is released may be used. Examples thereof include MF-5630 BLACK (manufactured by Dainichiseika Color & Chemicals Mfg. Co., Ltd.) and those described in paragraph [0035] of JP2009-132887A.

The volume average particle diameter of the inorganic particles included in the resin layer (B) is not particularly limited. However, from the viewpoint of improving film strength and maintaining favorable adhesiveness, the volume average particle diameter is preferably equal to or smaller than the film thickness of the resin layer (B), more preferably equal to or smaller than ½ of the film thickness of the resin layer (B), and even more preferably equal to or smaller than ⅓ of the film thickness of the resin layer (B).

The content of the inorganic particles in the resin layer (B) is preferably in a range of 10 vol % to 35 vol % and more preferably in a range of 20 vol % to 30 vol %.

—Crosslinking Agent—

The resin component included in the resin layer (B) may form a crosslinking structure using a crosslinking agent. That is, the resin layer (B) may include a crosslinking agent. When the crosslinking structure is formed in the resin layer (B), adhesiveness to an adjacent layer can be further improved, which is preferable. Examples of the crosslinking agent include an epoxy-based crosslinking agent, an isocyanate-based crosslinking agent, a melamine-based crosslinking agent, a carbodiimide-based crosslinking agent, and an oxazoline-based crosslinking agent. Specific examples of crosslinking agents include the same crosslinking agents as those that can be used in the undercoat layer, and preferable aspects are also the same.

—Catalyst for Crosslinking Agent—

In a case where the resin layer (B) includes the crosslinking agent, a catalyst for the crosslinking agent may be further included. When the resin layer (B) includes the catalyst for the crosslinking agent, a crosslinking reaction between the resin component and the crosslinking agent is accelerated, and the solvent resistance of the resin layer (B) is improved. In addition, as the crosslinking reaction favorably proceeds, adhesiveness between the resin layer (B) and the undercoat layer, or between the resin layer (B) and the resin layer (C), which will be described later, can be further improved.

Particularly, in a case where a crosslinking agent having an oxazoline group (oxazoline-based crosslinking agent) is used as the crosslinking agent, a catalyst for the crosslinking agent may be used.

Examples of the catalyst for the crosslinking agent include onium compounds.

As the onium compounds, ammonium salts, sulfonium salts, oxonium salts, iodonium salts, phosphonium salts, nitronium salts, nitrosonium salts, diazonium salts, and the like may be suitably employed.

As the catalyst for the crosslinking agent, the same catalysts for the crosslinking agent as those that can be used in the undercoat layer may be employed, and preferable aspects are also the same.

—Thickness of Resin Layer (B)—

The thickness of the resin layer (B) is preferably thicker than the thickness of the resin layer (C), which is an easy-adhesion layer described below, from the viewpoint of improving adhesiveness. That is, when the thickness of the resin layer (B) is represented by (b) and the thickness of the resin layer (C) is represented by (c), a relationship of (b)>(c) is preferable, and the ratio of (b) to (c) is more preferably in a range of 2:1 to 15:1.

In addition, the thickness of the resin layer (B) is preferably 0.5 μm or larger and more preferably 0.7 μm or larger. In addition, the thickness of the resin layer (B) is preferably 7.0 μm or smaller.

When the thickness of the resin layer (B) and the balance between the thickness of the resin layer (B) and the thickness of the resin layer (C) are in the above-described ranges, the characteristics of the resin component that forms the resin layer (B) are favorably exhibited, and adhesiveness between the solar cell protective sheet and the sealing material and the durability of the solar cell protective sheet are further improved in a case where the solar cell protective sheet is applied to a solar cell module.

—Method of Forming Resin Layer (B)—

As a method of forming the resin layer (B), for example, a method of applying a resin layer forming composition may be employed. The application method is preferable because a thin film with high uniformity can be simply formed. As the application method, for example, a well-known method using a gravure coater, a bar coater, or the like may be used.

After the application of the resin layer (B) forming composition, it is preferable to provide a process of drying the coating film (drying process). The drying process is a process of supplying dry air to the coating film. The average wind speed of the dry air is preferably 5 m/sec to 30 m/sec, more preferably 7 m/sec to 25 m/sec, and even more preferably 9 m/sec to 20 m/sec.

In a case where the resin layer (B) is formed through application, it is preferable that the drying of the coating film serves as a heat treatment in the drying process.

(Resin Layer (C))

In a case where the solar cell protective sheet has the above-described resin layer (B), it is preferable that the resin layer (C) is provided on a surface opposite to the undercoat layer of the resin layer (B).

It is preferable that the resin layer (C) is a layer which is positioned to be in direct contact with a sealing material for a solar cell module to which the solar cell protective sheet of the embodiment of the present invention is applied. That is, it is preferable that the resin layer (C) is a layer which is positioned as the outermost layer of the solar cell protective sheet and functions as an easy-adhesion layer.

The resin layer (C) includes at least a resin component and may include a variety of additives as desired.

As the resin component in the resin layer (C), one or more kinds of resins selected from an acrylic resin, a polyester resin, a polyurethane resin, a silicone-based compound, and a polyolefin resin may be employed. When the resins are used as the resin component, adhesiveness between the resin layer (C) and an adjacent layer is further improved. Examples of the resin component include resins described below.

As the acrylic resin, for example, a polymer containing polymethyl methacrylate, polyethyl acrylate, or the like is preferable.

As the acrylic resin, a commercially available product which is released may be used. Examples thereof include AS-563A (manufactured by Daicel FineChem Ltd.), and JURYMER (registered trademark) ET-410 and JURYMER SEK-301 (both manufactured by Toagosei Co., Ltd.).

Preferable examples of the polyester resin include polyethylene terephthalate (PET) and polyethylene-2,6-naphthalate (PEN).

As the polyester resin, a commercially available product which is released may be used. For example, VYLONAL (registered trademark) MD-1245 (manufactured by Toyobo Co., Ltd.) may be preferably used.

As the polyurethane resin, for example, a carbonate-based urethane resin is preferable, and for example, SUPERFLEX (registered trademark) 460 (manufactured by DKS Co. Ltd.) may be preferably used.

As the silicone-based compound, a compound having a (poly)siloxane structural unit, which will be described later, is preferable. As the silicone-based compound, a commercially available product which is released may be used. Examples thereof include CERANATE (registered trademark) WSA1060 and CERANATE WSA1070 (both manufactured by DIC Corporation), and H7620, H7630, and H7650 (all manufactured by Asahi Kasei Corporation).

As the polyolefin resin, for example, a modified polyolefin copolymer is preferable. As the polyolefin resin, a commercially available product which is released may be used. Examples thereof include ELEVES (registered trademark) SE-1013N, SD-1010, TC-4010, TD-4010 (all manufactured by Unitika Ltd.), HITECH 53148, 53121, 58512 (all manufactured by TOHO CHEMICAL INDUSTRY Co., Ltd.), and CHEMIPEARL (registered trademark) S-120, S-75N, V100, and EV210H (all manufactured by Mitsui chemicals, Inc.). Among these, it is preferable to use ELEVES (registered trademark) SE-1013N (manufactured by Unitika Ltd.), which is a terpolymer of low-density polyethylene, acrylic acid ester, and maleic anhydride, in terms of adhesion enhancement.

These resins may be used singly or in a combination of two or more kinds thereof.

In a case where the resins are used in a combination of two or more kinds thereof, a combination of an acrylic resin and a polyolefin resin, a combination of a polyester resin and a polyolefin resin, or a combination of a urethane resin and a polyolefin resin is preferable and a combination of an acrylic resin and a polyolefin resin is more preferable.

That is, it is preferable that the solar cell protective sheet has a structure in which at least two layers are laminated and the outermost layer includes an acrylic resin and a polyolefin resin.

In a case where a combination of an acrylic resin and a polyolefin resin is used, the content of the acrylic resin with respect to the total amount of the polyolefin resin and the acrylic resin in the resin layer (C) is preferably 3 mass % to 50 mass %, more preferably 5 mass % to 40 mass %, and particularly preferably 7 mass % to 25 mass %.

—Crosslinking Agent—

The resin component included in the resin layer (C) may form a crosslinking structure using a crosslinking agent. That is, the resin layer (C) may include a crosslinking agent. When the crosslinking structure is formed in the resin layer (C), adhesiveness to an adjacent layer can be further improved, which is preferable. Examples of the crosslinking agent include an epoxy-based crosslinking agent, an isocyanate-based crosslinking agent, a melamine-based crosslinking agent, a carbodiimide-based crosslinking agent, and an oxazoline-based crosslinking agent. Specific examples of crosslinking agents include the same crosslinking agents as those that can be used in the undercoat layer, and preferable aspects are also the same.

Among these, as the crosslinking agent contained in the resin layer (C), an oxazoline-based crosslinking agent is preferable. Examples of the oxazoline-based crosslinking agent include EPOCROS (registered trademark) K2010E, K2020E, K2030E, WS-500, and WS-700 (all manufactured by Nippon Shokubai Co., Ltd.).

As the crosslinking agent, only one kind of crosslinking agent may be used, or a combination of two or more kinds of crosslinking agent may be used.

The amount of the crosslinking agent added is preferably 0.5 parts by mass to 50 parts by mass with respect to the resin component included in the resin layer (C), more preferably 3 parts by mass to 40 parts by mass, and particularly preferably 5 mass % or more and less than 30 mass %. Particularly, when the amount of the crosslinking agent added is 0.5 mass % or more, a sufficient crosslinking effect is obtained while maintaining the film strength and adhesiveness of the resin layer (C). When the amount thereof is 50 mass % or less, the pot life of a coating liquid can be maintained for a long period of time. When the amount thereof is less than 40 mass %, the properties of a coating surface can be improved.

—Catalyst for Crosslinking Agent—

In a case where the resin layer (C) includes the crosslinking agent, a catalyst for the crosslinking agent may be further included. When the resin layer (C) includes the catalyst for the crosslinking agent, a crosslinking reaction between the resin component and the crosslinking agent is accelerated, and the solvent resistance of the resin layer (C) is improved. In addition, as the crosslinking reaction favorably proceeds, adhesiveness between the resin layer (C) and the sealing material can be further improved.

Particularly in a case where an oxazoline-based crosslinking agent is used as the crosslinking agent, a catalyst for the crosslinking agent may be used.

Examples of the catalyst for the crosslinking agent include onium compounds.

As the onium compounds, ammonium salts, sulfonium salts, oxonium salts, iodonium salts, phosphonium salts, nitronium salts, nitrosonium salts, diazonium salts, and the like may be suitably employed.

As the catalyst for the crosslinking agent, the same catalysts for the crosslinking agent as those that can be used in the undercoat layer may be employed, and preferable aspects are also the same.

As the catalyst for the crosslinking agent, only one kind of catalyst may be used, and a combination of two or more kinds of catalyst may be used.

The amount of the catalyst for the crosslinking agent added is preferably, with respect to the crosslinking agent in the resin layer (C), in a range of 0.1 mass % to 15 mass %, more preferably in a range of 0.5 mass % to 12 mass %, even more preferably in a range of 1 mass % to 10 mass %, and particularly preferably 2 mass % to 7 mass %. An added amount of the catalyst for the crosslinking agent of 0.1 mass % or more with respect to the crosslinking agent means that the catalyst for the crosslinking agent is actively included. Due to the included catalyst for the crosslinking agent, a crosslinking reaction between the resin component and the crosslinking agent more favorably proceeds, and superior solvent resistance is obtained. In addition, when the content of the catalyst for the crosslinking agent is of 15 mass % or less, there is an advantage in terms of solubility, filterability of a coating liquid, and adhesiveness between the resin layer (C) and the sealing material.

The resin layer (C) may include a variety of additives in addition to the resin component as long as the effect of the embodiment of the present invention is not hindered.

Examples of the additives include an antistatic agent, an ultraviolet absorber, a colorant, and a preservative.

Examples of the antistatic agent include surfactants such as nonionic surfactants, organic conductive materials, inorganic conductive materials, and organic/inorganic composite conductive materials.

As the surfactants, nonionic surfactants and anionic surfactants are preferable, and among these, nonionic surfactants are more preferable. As the nonionic surfactants, a nonionic surfactant which has an ethylene glycol chain (polyoxyethylene chain —(CH₂—CH₂—O)ₙ—) but does not have a carbon-carbon triple bond (alkyne bond) is preferably employed. Furthermore, a nonionic surfactant having 7 to 30 ethylene glycol chains is more preferable.

Specific examples of the nonionic surfactants include hexaethylene glycol monododecyl ether, 3,6,9,12,15-pentaoxahexadecan-1-ol, polyoxyethylene phenyl ether, polyoxyethylene methyl phenyl ether, polyoxyethylene naphthyl ether, polyoxyethylene methyl naphthyl ether but are not limited thereto.

In a case where the surfactant is used as the antistatic agent, the content of the surfactant in the resin layer (C) is preferably, with respect to the total solid content of the resin layer (C), 2.5 mass % to 40 mass %, more preferably 5.0 mass % to 35 mass %, and even more preferably in a range of 10 mass % to 30 mass %.

With the content of the surfactant in the above-described range, the dropping of the partial discharge voltage in the solar cell protective sheet is suppressed, and adhesiveness between a sealing material for sealing a solar cell element and a sealing material (for example, EVA: ethylene-vinyl acetate copolymer) is favorably maintained.

Examples of the organic conductive materials include: cationic conductive compounds having a cationic substituent such as an ammonium group, an amine base, or a quaternary ammonium group in the molecule; anionic conductive compounds having an anionic group such as a sulfonate salt group, a phosphate salt group, and a carboxylate salt group; ionic conductive materials such as amphoteric conductive compounds having both an anionic substituent and a cationic substituent; and conductive polymer compounds having a conjugated polyene-based skeleton, such as polyacetylene, poly-p-phenylene, polyaniline, polythiophene, poly-p-phenylene vinylene, and polypyrrole.

Examples of the inorganic conductive materials include: oxides, suboxides, and hypooxides of materials primarily containing a group of inorganic substances such as gold, silver, copper, platinum, silicon, boron, palladium, rhenium, vanadium, osmium, cobalt, iron, zinc, ruthenium, praseodymium, chromium, nickel, aluminum, tin, zinc, titanium, tantalum, zirconium, antimony, indium, yttrium, lanthanum, magnesium, calcium, cerium, hafnium, or barium; mixtures of the group of inorganic substances and oxides, suboxides, and hypooxides of the group of inorganic substances (hereinafter, collectively referred to as an inorganic oxide); nitrides, subnitrides, and hyponitrides of materials primarily containing the group of inorganic substances; mixtures of the group of inorganic substances and nitrides, subnitrides, hyponitrides of the group of inorganic substances (hereinafter, collectively referred to as an inorganic nitride); oxynitrides, suboxynitrides, and hypooxynitrides of materials primarily containing the group of inorganic substances; mixtures of the group of inorganic substances and oxynitrides, suboxynitrides, and hypooxynitrides of the group of inorganic substances (hereinafter, collectively referred to as an inorganic nitrude); carbides, subcarbides, and hypocarbides of materials primarily containing the group of inorganic substances; mixtures of the group of inorganic substances and carbides, subcarbides, and hypocarbides of the group of inorganic substances (hereinafter, collectively referred to as an inorganic carbide); halides, subhalides, and hypohalides of at least one of fluorides, chlorides, bromides, or iodides of materials primarily containing the group of inorganic substances; mixtures of the group of inorganic substances and halides, subhalides, and hypohalides of the group of inorganic substances (hereinafter, collectively referred to as an inorganic halide); mixtures of the group of inorganic substances and sulfides, subsulfides, and hyposulfides of the group of inorganic substances (which are hereinafter generically referred to as an inorganic sulfide); mateirals obtained by doping the group of inorganic substances with heteroelements; carbon-based compounds such as graphite carbon, diamond-like carbon, carbon fibers, carbon nanotubes, and fullerenes (hereinafter, collectively referred to as a carbon-based compound); and mixtures thereof.

[Weather-Resistant Layer]

The solar cell protective sheet may have at least one of weather-resistant layers, which will be described below in detail, on the surface opposite to the side on which the undercoat layer of the laminated polyester film is provided (the rear surface of the biaxially oriented polyester film). When the solar cell protective sheet has the weather-resistant layer, effects of environments on the base material are suppressed, and weather resistance and durability are further improved.

Hereinafter, as the weather-resistant layer which is suitably used in the solar cell protective sheet, a coating layer (D) and a coating layer (E) will be described in detail as an example.

(Weather-Resistant Layer Including Binder, Colorant, and Scattering Particles: Coating Layer (D))

As the weather-resistant layer, a layer including a binder, a colorant, and scattering particles (coating layer (D)) may be employed. In a solar cell module having a laminated structure made up of a solar cell side substrate [=a transparent substrate on a side on which sunlight is incident (for example, a glass substrate or the like)]/an element structure portion including a solar cell element/a solar cell protective sheet, the coating layer (D) is preferably a rear surface protective layer disposed on a side of the base material (biaxially oriented polyester film) in the solar cell protective sheet opposite to a side on which the base material is in contact with the solar cell side substrate.

The coating layer (D) may have a single layer structure or a laminated structure made up of two or more layers. In the case of a single layer structure, an aspect in which a layer including a binder, a colorant, and scattering particles is disposed on a base material is preferable. On the other hand, in the case of the laminated structure made up of two or more layers, an aspect in which layers including the binder, the colorant, and the scattering particles are laminated on a base material into two or more layers, and an aspect in which a layer including the binder, the colorant, and the scattering particles is formed on a base material, a layer which includes a fluorine-based resin, which will be described later, and includes neither a colorant nor scattering particles (for example, the coating layer (E) described below in detail) is further laminated thereon, are preferable.

—Binder—

The binder used in the coating layer (D) may be a binder formed of any one of a resin component, an inorganic polymer, and a composite compound including a resin component and an inorganic polymer. When the coating layer (D) includes the above-mentioned components, adhesiveness to the base material or adhesiveness between layers in a case where the weather-resistant layer is caused to have a laminated structure made up of two or more layers can be improved, and deterioration resistance in a wet heat environment can be obtained.

The inorganic polymer is not particularly limited, and a well-known inorganic polymer may be used.

The resin component or the composite compound is not particularly limited, but a binder preferably includes at least one of a fluorine-based polymer or a silicone-based compound, more preferably includes at least one of a fluorine-based organic polymer or a silicone-acryl organic and inorganic composite compound, and particularly preferably includes a silicone-acryl organic and inorganic composite compound.

<<Silicone-Based Compound>>

The silicone-based compound is a compound having a (poly)siloxane structure in a molecular chain, and is not particularly limited. The silicone-based compound may be a homopolymer of a compound having a (poly)siloxane structural unit or a copolymer including a (poly)siloxane structural unit and another structural unit. The structural unit that copolymerizes with the (poly)siloxane structural unit is a non-siloxane-based structural unit.

Since the coating layer (D) includes the silicone-based compound, adhesiveness to an adjacent material such as the base material of the solar cell protective sheet and the coating layer (E), which will be described later, and durability in a wet heat environment can be further improved.

The silicone-based compound preferably has a siloxane structural unit represented by General Formula (1) below as the (poly)siloxane structure.

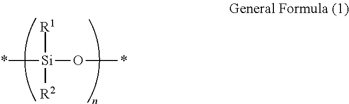

In General Formula (1), R¹ and R² each independently represent a hydrogen atom, a halogen atom, or a monovalent organic group. Here, R¹ and R² may be the same or different from each other, and a plurality of R¹'s or R²'s may be the same or different from each other. n represents an integer of 1 or higher.

A partial structure of “—(Si(R¹)(R²)—O)n-”, which is the siloxane structural unit in the silicone-based compound, is a siloxane segment capable of forming a variety of (poly)siloxane structures having a linear, branched, or cyclic structure.

In a case where R¹ and R² represent a halogen atom, As the halogen atom, a fluorine atom, a chlorine atom, an iodine atom, and the like may be employed.

In a case where R¹ and R² represent a monovalent organic group, the monovalent organic group may be any group capable of forming a covalent bond to a Si atom. Examples thereof include an alkyl group (for example, a methyl group or an ethyl group), an aryl group (for example, a phenyl group), an aralkyl group (for example, a benzyl group, phenyl ethyl, or the like), an alkoxy group (for example, a methoxy group, an ethoxy group, or a propoxy group), an aryloxy group (for example, a phenoxy group), a mercapto group, an amino group (for example, an amino group or a diethylamino group), and an amide group. These organic groups may be unsubstituted groups or may further have a substituent.

Among these, in terms of adhesiveness to an adjacent layer and durability in a wet heat environment, it is preferable that R¹ and R² are each independently a hydrogen atom, a chlorine atom, a bromine atom, an unsubstituted or substituted alkyl group having 1 to 4 carbon atoms (particularly, a methyl group or an ethyl group), an unsubstituted or substituted phenyl group, an unsubstituted or substituted alkoxy group, a mercapto group, an unsubstituted amino group, or an amide group. In terms of durability in a wet heat environment, it is more preferable that R¹ and R² are an unsubstituted or substituted alkoxy group (preferably an alkoxy group having 1 to 4 carbon atoms).

n is preferably 1 to 5000 and more preferably 1 to 1000.

The proportion of a portion of “—(Si(R¹) (R²)—O)ₙ—” (the (poly)siloxane structural unit represented by General Formula (1)) in the silicone-based compound is preferably 15 mass % to 85 mass % of the total mass of the silicone-based compound. Particularly, from the viewpoint of improving the film strength of the coating layer (D), preventing the generation of scratches caused by scratching, abrasion, or the like, and further improving adhesiveness to an adjacent layer and durability in a wet heat environment, a range of 20 mass % to 80 mass % is more preferable. When the proportion of the (poly)siloxane structural unit is 15 mass % or higher, the film strength of the coating layer (D) is improved, the generation of scratches caused by scratching, abrasion, collisions with flying pebbles, or the like is prevented, and excellent adhesiveness to an adjacent layer is achieved. The prevention of the generation of scratches improves weather resistance, and peeling resistance which is likely to deteriorate due to heat or moisture, shape stability, and durability during exposure to a wet heat environment can be effectively enhanced. In addition, when the proportion of the (poly)siloxane structural unit is 85 mass % or lower, a coating liquid can be stably maintained.

In a case where the silicone-based compound is a copolymer having the (poly)siloxane structural unit and another structural unit, the (poly)siloxane structural unit represented by General Formula (1) is preferably included in the molecular chain in a proportion of 15 mass % to 85 mass % by mass, and a non-siloxane-based structural unit is preferably included in a proportion of 85 mass % to 15 mass % by mass. When the above-described copolymer is included in the coating layer (D), the film strength of the coating layer (D) is improved, the generation of scratches caused by scratching, abrasion, or the like is prevented, adhesiveness to an adjacent layer, that is, peeling resistance which is likely to deteriorate due to heat and moisture, shape stability, and durability in a wet heat environment can be significantly improved compared to the related art.

The copolymer is preferably a block copolymer which has the (poly)siloxane structural unit represented by General Formula (1) and a non-siloxane-based structural unit formed through copolymerization of a siloxane compound (including polysiloxane) and a non-siloxane-based monomer or a compound selected from non-siloxane-based polymers. In this case, as the siloxane compound and the non-siloxane-based monomer or the non-siloxane-based polymer to be copolymerized, only one kind may be singly used, or two or more kinds may be used.

The non-siloxane-based structural unit copolymerized with the (poly)siloxane structural unit (derived from a non-siloxane-based monomer or a non-siloxane-based polymer) is not particularly limited except that the non-siloxane-based structural unit does not have a siloxane structure and may be any polymer segment derived from an arbitrary polymer. Examples of a polymer which is a precursor of the polymer segment (precursor polymer) include a variety of polymers such as a vinyl-based polymer, a polyester-based polymer, and a polyurethane-based polymer.

Among these, in terms of ease of preparation and excellent hydrolysis resistance, a vinyl-based polymer and a polyurethane-based polymer are preferable, and a vinyl-based polymer is particularly preferable.

Representative examples of the vinyl-based polymer include a variety of polymers such as an acrylic polymer, a carboxylic acid vinyl ester-based polymer, an aromatic vinyl-based polymer, and a fluoroolefin-based polymer. Among these, from the viewpoint of the degree of freedom of design, an acrylic polymer is particularly preferable.

In addition, as a polymer forming the non-siloxane-based structural unit, one kind of polymer may be singly used, or two or more kinds of resin may be used in combination.

In addition, the precursor polymer capable of forming the non-siloxane-based structural unit preferably includes at least one of acid groups or neutralized acid groups and/or a hydrolyzable silyl group. Among these precursor polymers, the vinyl-based polymer can be prepared using a variety of methods such as (1) a method in which a vinyl-based monomer including an acid group and a vinyl-based monomer including a hydrolyzable silyl group and/or a silanol group are copolymerized with a monomer capable of being copolymerized with the these monomers, (2) a method in which a polycarboxylic acid anhydride is caused to react with a vinyl-based polymer including a hydroxyl group prepared in advance and a hydrolyzable silyl group and/or a silanol group, and (3) a method in which a vinyl-based polymer including an acid anhydride group prepared in advance and a hydrolyzable silyl group and/or a silanol group is caused to react with a compound having active hydrogen (water, an alcohol, an amine, or the like).

The precursor polymer can be manufactured or procured using, for example, the method described in paragraphs [0021] to [0078] of JP2009-52011A.

In the coating layer (D), as the binder, the silicone-based compound may be used singly or in combination with another resin component, an inorganic polymer, or a composite compound. In a case where the silicone-based compound and another resin component, an inorganic polymer, or a composite compound are used in combination, the content of the silicone-based compound is preferably 30 mass % or more and more preferably 60 mass % or more of the total amount of the binder. When the content of the silicone-based compound is 30 mass % or more, the film strength of the coating layer (D) is improved, the generation of scratches caused by scratching, abrasion, or the like is prevented, and excellent adhesiveness to an adjacent layer and excellent durability in a wet heat environment are achieved.

The molecular weight of the silicone-based compound is preferably 5,000 to 100,000 and more preferably 10,000 to 50,000.

For the preparation of the silicone-based compound, methods such as (i) a method in which the precursor polymer and polysiloxane having the structural unit represented by General Formula (1) are caused to react with each other or (ii) a method in which a silane compound having the structural unit represented by General Formula (1) in which R¹ and/or R² are hydrolyzable groups undergoes hydrolytic condensation in the presence of the precursor polymer.

A variety of silane compounds may be used as the silane compound used in the (ii) method, and an alkoxysilane compound is particularly preferable.

In a case where the silicone-based compound is prepared using the (i) method, for example, the silicone-based compound can be prepared by adding water and a catalyst as necessary to a mixture of the precursor polymer and polysiloxane and causing a reaction in the mixture at a temperature of about 20° C. to 150° C. for about 30 minutes to 30 hours (preferably at 50° C. to 130° C. for 1 hour to 20 hours). As the catalyst, a variety of silanol condensation catalysts such as an acidic compound, a basic compound, and a metal-containing compound may be added.

In addition, in a case where the silicone-based compound is prepared using the (ii) method, for example, the polymer can be prepared by adding water and a silanol condensation catalyst to a mixture of the precursor polymer and an alkoxysilane compound and causing hydrolytic condensation at a temperature of about 20° C. to 150° C. for about 30 minutes to 30 hours (preferably at 50° C. to 130° C. for 1 hour to 20 hours).

As the silicone-based compound, a commercially available product which is released may be used. For example, CERANATE (registered trademark) series (for example, CERANATE (registered trademark) WSA1070 and CERANATE WSA1060) manufactured by DIC Corporation, H7600 series (H7650, H7630, H7620, and the like) manufactured by Asahi Kasei Corporation, and an inorganic acryl composite emulsion manufactured by JSR Corporation may be used.

The amount of the silicone-based compound applied to the coating layer (D) is preferably in a range of more than 0.2 g/m² and equal to or less than 15 g/m². When the amount of the applied silicone-based compound is in the above-described range, scratches generated due to an external force exerted on the solar cell protective sheet can be prevented.

In the above-described range, from the viewpoint of the film strength of the coating layer (D), a range of 0.5 g/m² to 10.0 g/m² is preferable, and a range of 1.0 g/m² to 5.0 g/m² is more preferable.

Among the above-described products, the coating layer (D) preferably has a form configured by using CERANATE (registered trademark) series manufactured by DIC Corporation or an inorganic acryl composite emulsion manufactured by JSR Corporation as the silicone-based compound.

—Fluorine-Based Resin—

The coating layer (D) may be formed by using a fluorine-based resin as a primary binder. The primary binder refers to a binder having the largest content in the layer.

The fluorine-based resin that can be used here is not particularly limited as long as the fluorine-based resin is a resin having a repeating unit represented by —(CFX¹—CX²X³)— (here, X¹, X², and X³ each independently represents a hydrogen atom, a fluorine atom, a chlorine atom, or a fluoroalkyl group having 1 to 3 carbon atoms).

Specific examples thereof include polytetrafluoroethylene (hereinafter, in some cases, referred to as PTFE), polyvinyl fluoride (hereinafter, in some cases, referred to as PVF), polyvinylidene fluoride (hereinafter, in some cases, referred to as PVDF), polychlorotrifluoroethylene (hereinafter, in some cases, referred to as PCTFE), and polytetrafluoropropylene (hereinafter, in some cases, referred to as HFP).

The fluorine-based resin may be a homopolymer obtained through polymerization of identical monomers or a copolymer obtained through copolymerization of two or more monomers. Examples of the copolymer obtained through copolymerization of two or more monomers include a copolymer obtained through copolymerization of tetrafluoroethylene and tetrafluoropropylene (abbreviated as P(TFE/HFP)), and a copolymer obtained through copolymerization of tetrafluoroethylene and vinylidene fluoride (abbreviated as P(TFE/VDF)).

Furthermore, the fluorine-based resin may be a copolymer obtained through copolymerization of a fluorine-based structural unit represented by —(CFX¹—CX²X³)— and another structural unit. Examples thereof include a copolymer of tetrafluoroethylene and ethylene (hereinafter, abbreviated as P(TFE/E)), a copolymer of tetrafluoroethylene and propylene (abbreviated as P(TFE/P)), a copolymer of tetrafluoroethylene and vinyl ether (abbreviated as P(TFE/VE)), a copolymer of tetrafluoroethylene and perfluorovinyl ether (abbreviated as P(TFE/FVE)), a copolymer of chlorotrifluoroethylene and vinyl ether (abbreviated as P(CTFE/VE)), and a copolymer of chlorotrifluoroethylene and perfluorovinyl ether (abbreviated as P(CTFE/FVE)).

The fluorine-based resin may be used by dissolving the resin in an organic solvent, or may be used by dispersing the resin in water. The latter is preferable in terms of low environmental load. Water dispersoids of the fluorine-based resin are described in, for example, JP2003-231722A, JP2002-20409A, and JP1997-194538A (JP-H09-194538A) as a reference, and the resins described therein can be applied.

As the binder for the coating layer (D), the above-described fluorine-based resins may be used singly, or in a combination of two or more kinds thereof. In addition, in a case where the fluorine-based resin is used as the primary binder of the coating layer (D), a resin other than the fluorine-based resin, such as an acrylic resin, a polyester resin, a polyurethane resin, a polyolefin resin, or a silicone-based compound may be used in combination in a range of 50 mass % or less of the total amount of the binder.

In the coating layer (D), the content of the binder component (including the silicone-based compound) is preferably in a range of 15 parts by mass to 200 parts by mass with respect to 100 parts by mass of scattering particles, which will be described later, and more preferably in a range of 17 parts by mass to 100 parts by mass. When the content of the binder is 15 parts by mass or more, a colored layer can obtain sufficient strength, and when the content of the binder is 200 parts by mass or less, reflectivity or designability can be favorably maintained.

—Colorant—

The colorant that can be used in the coating layer (D) is not particularly limited, and a well-known dye or a well-known pigment may be used. In this specification, the colorant does not include scattering particles, which will be described later. As the colorant, a black colorant, a green-based colorant, a blue-based colorant, a red-based colorant, and the like may be employed.

The colorant that can be used in the coating layer (D) preferably includes at least one kind selected from carbon black, titanium black, a black complex metal oxide, a cyanine-based color, and a quinacridone-based color. In addition, the colorant may be selected depending on required optical density.

The black complex metal oxide is preferably a complex metal oxide including at least one of iron, manganese, cobalt, chromium, copper, or nickel, preferably includes two or more of cobalt, chromium, iron, manganese, copper, and nickel, and is even more preferably at least one pigment selected from pigments having color indexes PBk26, PBk27, PBk28, and PBr34. In addition, a pigment of PBk26 is a complex oxide of iron, manganese, and copper, a pigment of PBk27 is a complex oxide of iron, cobalt, and chromium, a pigment of PBk-28 is a complex oxide of copper, chromium, and manganese, and a pigment of PBr34 is a complex oxide of nickel and iron. As the cyanine-based color and the quinacridone-based color, cyanine green, cyanine blue, quinacridone red, phthalocyanine blue, phthalocyanine green, and the like may be employed.

Among these, carbon black is preferably used as the colorant from the viewpoint of easily controlling the optical density such that the optical density to be in the above-described preferable range or from the viewpoint of controlling the optical density with a small amount of the colorant.

The carbon black is preferably carbon black fine particles having a volume average particle of 0.1 μm to 0.8 μm. The volume average particle diameter can be measured according to the above-described method.

Furthermore, it is preferable that the carbon black is dispersed in water together with a dispersant for use.

As the carbon black, a commercially available product which is released may be used. Examples thereof include MF-5630 BLACK (manufactured by Dainichiseika Color & Chemicals Mfg. Co., Ltd.) and those described in paragraph “0035” of JP2009-132887A.

—Scattering Particles—

The scattering particles that can be included in the coating layer (D) are not particularly limited, and well-known scattering particles may be used. The scattering particles indicate particles that barely absorb light in the visual range and do not include the colorant described above. A white pigment is preferably used as the scattering particles.

As the white pigment that can be used as the scattering particles, inorganic pigments such as titanium dioxide, barium sulfate, silicon oxide, aluminum oxide, magnesium oxide, calcium carbonate, kaolin, talc, and colloidal silica, organic pigments such as hollow particles, and the like may be employed. Among these, titanium dioxide is preferable.

As the crystalline form of titanium dioxide, there are a rutile form, an anatase form, and a brookite form, and a rutile form is preferable. The titanium dioxide may be subjected to a surface treatment as necessary using aluminum oxide (Al₂O₃), silicon dioxide (SiO₂), an alkanolamine compound, a silicon compound, or the like.

Particularly, when titanium dioxide having a bulk specific gravity of 0.50 g/cm³ or higher is used, titanium dioxide is densely packed, and the film strength of the coating layer (D) is improved. On the other hand, when titanium dioxide having a bulk specific gravity of 0.85 g/cm³ or lower, the dispersibility of titanium dioxide can be favorably maintained, and the coating layer (D) can achieve excellent surface properties. The bulk specific gravity of titanium dioxide used in the coating layer (D) is particularly preferably 0.60 g/cm³ or higher and 0.80 g/cm³ or lower.

The bulk specific gravity is a value measured according to the following method.

(1) A colorant is caused to pass through a sieve with a mesh of 1.0 mm. (2) About 100 g of the colorant is weighed (m) and is gently put into a 250 mL graduated cylinder. As necessary, after putting the colorant is finished, the upper surface thereof is carefully leveled without consolidation, and the volume (V) is measured. (3) The bulk specific gravity is obtained according to the following expression. Bulk specific gravity=m/V (unit: g/cm³)

When the coating layer (D) further includes a white pigment as the scattering particles in addition to the binder such as a silicone-based compound or a fluorine-based resin, the reflectivity of the coating layer (D) can be increased, and yellowing in a long-term high-temperature and humidity test (conducted at 85° C. and a relative humidity of 85% for 2000 hours to 3000 hours) and a ultraviolet (UV) irradiation test (according to the UV test of IEC61215, the total irradiance is 45 Kwh/m²) can be suppressed. Furthermore, when the scattering particles are added to the coating layer (D), adhesiveness to an adjacent layer is further improved.

In a case where the scattering particles are used in the coating layer (D), the amount of the scattering particles applied to the coating layer (D) is preferably in a range of 1.0 g/m² to 15 g/m² per layer. When the content of the scattering particles (preferably the white pigment) is 1.0 g/m² or more, reflectivity and UV resistance (light resistance) can be effectively imparted thereto. When the content of the scattering particles (preferably the white pigment) in the coating layer (D) is 15 g/m² or less, the surface properties of the coating layer (D) are likely to be favorably maintained, and excellent film strength is achieved. Particularly, the content of the scattering particles included in the coating layer (D) is more preferably in a range of 2.5 g/m² to 10 g/m², and particularly preferably in a range of 4.5 g/m² to 8.5 g/m².

The volume average particle diameter of the scattering particles is preferably 0.03 μm to 0.8 μm and more preferably 0.15 μm to 0.5 μm. When the volume average particle diameter is within the above-described range, a high light reflectance is achieved. The volume average particle diameter can be measured according to the above-described method.

—Other Components—

In a case where a solar cell protective sheet includes the coating layer (D) including the binder, the colorant, and the scattering particles, the solar cell protective sheet may further include, as necessary, other components such as a variety of additives, for example, a crosslinking agent, a surfactant, and a filler.

Among these, it is preferable to add a crosslinking agent so as to form a crosslinking structure derived from the crosslinking agent and the binder in the coating layer (D) from the viewpoint of further improving the film strength and durability of the coating layer (D).

Examples of the crosslinking agent include an epoxy-based crosslinking agent, an isocyanate-based crosslinking agent, a melamine-based crosslinking agent, a carbodiimide-based crosslinking agent, and an oxazoline-based crosslinking agent. Among these, the crosslinking agent is preferably at least one crosslinking agent selected from a carbodiimide-based crosslinking agent, an oxazoline-based crosslinking agent, and an isocyanate-based crosslinking agent.

As specific examples of the crosslinking agent, those described for the undercoat layer can be similarly applied to the coating layer (D), and preferable examples thereof are also the same.

In a case where the crosslinking agent is used in the coating layer (D), the amount of the crosslinking agent added is preferably 0.5 parts by mass to 30 parts by mass with respect to 100 parts by mass of the binder included in the coating layer (D), and more preferably 3 parts by mass or more and less than 15 parts by mass. When the amount of the crosslinking agent added is 0.5 parts by mass or more, a sufficient crosslinking effect can be obtained while maintaining the film strength of the coating layer (D) and adhesiveness to an adjacent layer. When the amount of the crosslinking agent added is 30 parts by mass or less, the pot life of a coating liquid is maintained for long period of time. When the amount of the crosslinking agent added is less than 15 parts by mass, the properties of a coated surface can be improved.

As the surfactant that can be used in the coating layer (D), a well-known surfactant such as an anionic surfactant and a nonionic surfactant may be employed. In a case where the surfactant is used in the coating layer (D), the amount of the surfactant added is preferably 0.1 mg/m² to 10 mg/m² and more preferably 0.5 mg/m² to 3 mg/m². When the amount of the surfactant added is 0.1 mg/m² or more, a layer in which the generation of cissing is suppressed is obtained. When the amount of the surfactant added is 10 mg/m² or less, excellent adhesiveness to an adjacent layer is achieved.

A filler may be added to the coating layer (D). As the filler, a well-known filler such as colloidal silica may be used.

The coating layer (D) can be formed by applying and drying a coating liquid including the binder and the like (coating layer (D) forming composition) onto the surface on the rear surface side of the base material (the surface opposite to the side where the undercoat layer of the laminated polyester film is provided), and drying the resultant.

In the solar cell protective sheet, it is preferable that the coating layer (D) is a layer formed by applying the coating layer (D) forming composition including at least one of the fluorine-based resin or the silicone-based compound.

The application process is preferable because a thin film with high uniformity can be simply formed. As an application method, for example, a well-known method using a gravure coater, a bar coater, or the like may be used. As a solvent for the coating layer (D) forming composition used in the application process, water may be used, or an organic solvent such as toluene or methyl ethyl ketone may be used. As the solvent, one kind of solvent may be singly used, or a mixture of two or more kinds of solvent may be used. From the viewpoint of environmental load, water is preferably used as the solvent.

In a case where water is used as the solvent, a combination of water and an organic solvent may be used, and the content of water in the solvent is preferably 60 mass % or more with respect to the total mass of the solvent, and more preferably 80 mass % or more.

As the coating layer (D) forming composition, an aspect in which an aqueous dispersion liquid in which the binder and other components used in combination with the binder as desired are dispersed in water is prepared, and the aqueous dispersion liquid is applied onto a desired base material as the coating layer (D) forming composition is preferable.

After the application of the coating layer (D) forming composition, it is preferable to provide a process of drying the coating film. The drying temperature in the drying process may be appropriately selected depending on the composition of the coating liquid and the application amount.

In addition, the application to the base material may be carried out on the biaxially oriented polyester film, the polyester film stretched in the first direction, or the un-stretched polyester film.

—Thickness of Coating Layer (D)—

The thickness of the coating layer (D) is typically preferably 1 μm to 30 μm, more preferably 5 μm to 25 μm, and even more preferably 10 μm to 20 μm. When the thickness thereof is within the above-described range, moisture is less likely to penetrate into the coating layer (D) during exposure to an wet heat environment. In addition, since moisture is less likely to reach the interface between the coating layer (D) and the base material, adhesiveness is significantly improved, the film strength of the coating layer (D) itself is favorably maintained, and the weather-resistant layer is less likely to break during exposure to a wet heat environment.

(Weather-Resistant Layer Including Fluorine-Based Polymer: Coating Layer (E))

The solar cell protective sheet may further include the coating layer (E) including a fluorine-based resin on the surface of the coating layer (D).

In a case where the solar cell protective sheet includes the coating layer (E) including a fluorine-based resin, it is preferable that the coating layer (E) is provided directly on the surface of the coating layer (D) that is arbitrarily provided on the base material. The coating layer (E) is preferably positioned at the outermost layer of the solar cell protective sheet. That is, it is preferable that the weather-resistant layer has a structure in which two layers are laminated, and the weather-resistant layer farthest from the laminated polyester film includes a fluorine-based resin.

The coating layer (E) including a fluorine-based resin is preferably configured using a fluorine-based resin as a primary binder. The primary binder refers to a binder having the largest content in the coating layer (E).

Hereinafter, the coating layer (E) and the fluorine-based resin included therein will be described in detail.

—Fluorine-Based Resin—

The fluorine-based resin is not particularly limited as long as the fluorine-based resin is a polymer having a repeating unit represented by —(CFX¹—CX²X³)— (in the expression, X¹, X², and X³ each independently represent a hydrogen atom, a fluorine atom, a chlorine atom, or a fluoroalkyl group having 1 to 3 carbon atoms).

As the fluorine-based resin, the same resin as the fluorine-based resin used for the coating layer (D) may be employed, and specific examples and preferable examples thereof are also the same.

The fluorine-based resin may be used by dissolving the resin in an organic solvent, or may be used by dispersing the resin particles in an appropriate dispersion medium such as water. From the viewpoint of low environmental load, a resin particle dispersoid for which water or a water-based solvent is used as a dispersion medium is preferably used. Water dispersoids of the fluorine-based resin are described in, for example, JP2003-231722A, JP2002-20409A, and JP1997-194538A (JP-H09-194538A) as a reference, and these may be used for the formation of the coating layer (E).

As the binder of the coating layer (E), the fluorine-based resin may be used singly or two or more kinds of resin component may be used in combination. In a case where two or more kinds of resin component are used in combination, a resin other than the fluorine-based resin, such as an acrylic resin, a polyester resin, a polyurethane resin, a polyolefin resin, or a silicone-based compound may be used in combination in a range of 50 mass % or less of the total amount of the binder. However, when the fluorine-based resin is included in coating layer (E) in a proportion of higher than 50 mass %, an effect of improving weather resistance is more favorably exhibited.

—Lubricant—

The coating layer (E) preferably includes at least one kind of lubricant.

When the coating layer includes a lubricant, a reduction in slippage, which is easily caused in a case where a fluorine-containing polymer is used, (that is, an increase in the coefficient of kinetic friction) is suppressed, and thus susceptibleness to damage caused by an external force such as scratching, abrasion, or collisions with flying pebbles is significantly alleviated. In addition, the cissing of a coating liquid on the surface, which is easily caused in a case where the fluorine-based resin is used, can be prevented, and the coating layer (E) with favorable surface properties can be formed.

It is preferable that the lubricant is included in the coating layer (E) in a proportion in a range of 0.2 mg/m² to 200 mg/m². When the content of the lubricant is 0.2 mg/m² or more, the effect of reducing the coefficient of kinetic friction increases. When the content of the lubricant is 200 mg/m² or less, coating unevenness and generation of aggregates are prevented when the coating layer (E) is formed through application, and thus generation of cissing is prevented.

In the above-described range, from the viewpoint of the effect of reducing the coefficient of kinetic friction and coating suitability, the content of the lubricant is preferably in a range of 1.0 mg/m² to 1150 mg/m² and more preferably in a range of 5.0 mg/m² to 100 mg/m².

Examples of the lubricant include a synthetic wax-based compound, a natural wax-based compound, a surfactant-based compound, an inorganic compound, and an organic resin-based compound. Among these, in terms of the surface strength of the coating layer (E), a compound selected from a synthetic wax-based compound, a natural wax-based compound, and a surfactant-based compound is preferable.

Examples of the synthetic wax-based compound include: an olefin-based wax such as a polyethylene wax and a polypropylene wax; esters such as stearic acid, oleic acid, erucic acid, lauric acid, behenic acid, palmitic acid, and adipic acid; an amide, a bisamide, a ketone, a metallic salt, and derivatives thereof; a synthetic hydrocarbon wax such as a Fischer-Tropsch wax; and a hydrogenated wax such as phosphoric acid ester, hardened castor oil, and a derivative of hardened castor oil.

Examples of the natural wax-based compound include: a plant-based wax such as carnauba wax, candelilla wax, and Japan wax; a petroleum-based wax such as paraffin wax and microcrystalline wax; a mineral-based wax such as montan wax; and an animal-based wax such as a beeswax and lanolin.

Examples of the surfactant include a cationic surfactant such as an alkyl amine salt, an anionic surfactant such as an alkylsulfuric acid ester salt, a nonionic surfactant such as polyoxyethylene alkyl ether, an amphoteric surfactant such as an alkyl betaine, and a fluorine-based surfactant.

As the lubricant, a commercially available product which is released may be used. Specifically,
examples of the synthetic wax-based compound include CHEMIPAL (registered trademark) series manufactured by Mitsui Chemicals, Inc. (for example, CHEMIPAL (registered trademark) W700, CHEMIPAL W900, and CHEMIPAL W950), and POLYRON P-502, HYMICRON L-271, and HIDORIN L-536 manufactured by Chukyo Yushi Co., Ltd.,
examples of the natural wax-based compound include HIDORIN L-703-35, SELOSOL 524, and SELOSOL R-586 manufactured by Chukyo Yushi Co., Ltd., and
examples of the surfactant include NIKKOL (registered trademark) series manufactured by Nikko Chemicals Co., Ltd. (for example, NIKKOL (registered trademark) SCS), and EMAL (registered trademark) series manufactured by Kao Corporation (for example, EMAL (registered trademark) 40).

—Other Additives—

To the coating layer (E), colloidal silica, a silane coupling agent, a crosslinking agent, a surfactant, and the like may be added as necessary.

As the colloidal silica, the same colloidal silica as that used for the resin layer (B) may be employed, and preferable aspects are also the same.

In a case where the coating layer (E) includes colloidal silica, the content thereof in the total solid content of the coating layer (E) is preferably 0.3 mass % to 1.0 mass % and more preferably 0.5 mass % to 0.8 mass %. When the content thereof is set to 0.3 mass % or more, an effect of improving surface properties can be obtained. When the content thereof is set to 1.0 mass % or less, aggregation of the coating layer (E) forming composition can be more effectively prevented.

In a case where the coating layer (E) includes colloidal silica, a silane coupling agent is preferably used in combination therewith from the viewpoint of improving surface properties.

The silane coupling agent is preferably an alkoxysilane compound, and examples thereof include tetraalkoxysilanes and trialkoxysilanes. Among these, a trialkoxysilane is preferable, and an alkoxysilane compound having an amino group is preferable.

In a case where a silane coupling agent is used in combination therewith, the amount of the silane coupling agent added is preferably 0.3 mass % to 1.0 mass % with respect to the total solid content of the coating layer (E), and particularly preferably 0.5 mass % to 0.8 mass %. When the amount of the silane coupling agent added is set to 0.3 mass % or more, an effect of improving surface properties can be obtained. When the amount of the silane coupling agent added is set to 1.0 mass % or less, aggregation of the coating layer (E) forming composition can be more effectively prevented.

From the viewpoint of improving weather resistance, it is preferable to add a crosslinking agent to the coating layer (E) so as to form a crosslinking structure derived from the binder and the crosslinking agent. As the crosslinking agent that can be used for the coating layer (E), the same crosslinking agent as that used for the undercoat layer may be employed.

As the surfactant used for the coating layer (E), a well-known surfactant such as an anionic surfactant and a nonionic surfactant may be used. In a case where the surfactant is added to the coating layer (E), the amount of the surfactant added is preferably 0 mg/m² to 15 mg/m² and more preferably 0.5 mg/m² to 5 mg/m². When the amount of the surfactant added is 0.1 mg/m² or more, generation of cissing is suppressed, and thus a favorable layer can be formed. When the amount of the surfactant added is 15 mg/m² or less, adhesiveness to an adjacent layer is further improved.

—Thickness—

The thickness of the coating layer (E) is typically preferably 0.5 μm to 12 μm, more preferably 0.5 μm to 5 μm, and even more preferably in a range of 0.8 μm to 3 μm.

When the thickness thereof is within the above-described range, weather resistance and durability are further improved, and deterioration in the properties of the coated surface is prevented.

The solar cell protective sheet may have another layer laminated on (the outer layer on) the coating layer (E). However, from the viewpoint of improving durability of the solar cell protective sheet, reducing the weight, thickness, and costs, the coating layer (E) is preferably the outermost layer of the solar cell protective sheet.

—Other Layers—

### (Gas Barrier Layer)

A gas barrier layer may be provided on a surface opposite to the resin layer (B) of the base material. The gas barrier layer is a layer for imparting a moisture-proof function to prevent penetration of water or gas into the base material.

The amount of water vapor penetrating through the gas barrier layer (moisture permeability) is preferably 10² g/m²·day to 10⁻⁶ g/m²·day, more preferably 10¹ g/m²·day to 10⁻⁵ g/m²·day, and even more preferably 10⁰ g/m²·day to 10⁻⁴ g/m²·day.

As a method of forming the gas barrier layer having such moisture permeability, a dry method is suitable. Examples of the dry method include: a vacuum vapor deposition method such as resistance heating vapor deposition, electron beam vapor deposition, induced heating vapor deposition, and an assistance method in which plasma or ion beams are used for the above-mentioned methods; a sputtering method such as a reactive sputtering method, an ion beam sputtering method, and an electron cyclotron resonance (ECR) sputtering method; a physical vapor deposition method (PVD method) such as an ion plating method; and a chemical vapor deposition method (CVD method) in which heat, light, plasma, or the like is used. Among these, a vacuum vapor deposition method in which a film is formed using a vapor deposition method in a vacuum is preferable.

Examples of a material for forming the gas barrier layer include an inorganic oxide, an inorganic nitride, an inorganic oxynitride, an inorganic halide, and an inorganic sulfide.

Otherwise, an aluminum foil may be attached to the base material so as to be used as the gas barrier layer.

The thickness of the gas barrier layer is preferably 1 μm to 30 μm. When the thickness thereof is 1 μm or greater, the gas barrier layer does not easily allow water to penetrate into the base material during exposure to moisture and heat for a period of time (thermo) and excellent hydrolysis resistance is achieved. When the thickness thereof is 30 μm or smaller, an inorganic layer does not become excessively thick, and accretion in the base material due to stresses in the inorganic layer does not occur.

<Solar Cell Module>

The solar cell module includes the solar cell protective sheet having the above-described laminated polyester film.

Since the adhesiveness of the solar cell protective sheet having the above-described laminated polyester film, which is included in the solar cell module, to an adjacent layer is excellent for a long period of time, the solar cell module can stably maintain power generation performance for a long period of time.

Specifically, the solar cell module is provided with a transparent substrate (a front substrate such as a glass substrate) on which sunlight is incident, an element structure portion which is provided on the substrate and has a solar cell element and a sealing material that seals the solar cell element, and the solar cell protective sheet having the laminated polyester film disposed on a side opposite to a side on which the substrate such as the glass substrate of the element structure portion is positioned, and thus has a laminated structure made up of the transparent front substrate, the element structure portion, and the solar cell protective sheet. Specifically, a configuration is achieved in which the element structure portion in which the solar cell element for converting the energy of sunlight into electrical energy is disposed is disposed between the transparent front substrate disposed on the side on which sunlight is directly incident and the solar cell protective sheet, and the element structure portion (for example, a solar cell) including the solar cell element is sealed with and attached to the sealing material such as an ethylene-vinyl acetate copolymer (EVA) between the front substrate and the solar cell protective sheet. The solar cell protective sheet has excellent adhesiveness particularly to EVA, and an improvement in long-term durability can be achieved.

Members other than the solar cell module, the solar cell, and the solar cell protective sheet are described in detail, for example, in “Solar Power System Constitutive Materials” (edited by EIICHI SUGIMOTO and published by KOGYO CHOSAKAI PUBLISHING in 2008).

The transparent substrate may have a light-transmitting property so as to be capable of transmitting sunlight and may be appropriately selected from substrates that transmit light. From the viewpoint of power generation efficiency, it is preferable that the light transmittance is as high as possible, as such substrates, for example, a glass substrate and a transparent resin substrate such as an acrylic resin may be suitably used.

Examples of the solar cell element include a variety of well-known solar cell elements such as a solar cell element based on silicon such as monocrystalline silicon, polycrystalline silicon, or amorphous silicon, or a solar cell element based on a III-V group or II-VI group compound semiconductor such as copper-indium-gallium-selenium, copper-indium-selenium, cadmium-tellurium, and gallium-arsenic. A space between the substrate and the solar cell protective sheet may be configured to be sealed with a resin (so-called sealing material) such as an ethylene-vinyl acetate copolymer.

### EXAMPLES

Hereinafter, an embodiment of the present invention will be described in detail using examples, but the present invention is not limited to the following examples within the scope of the gist of the present invention. In addition, unless otherwise defined, “parts” is based on mass.

—Synthesis of Polyester—

100 kg of high-purity terephthalic acid (manufactured by Mitsui Chemicals, Inc.) and 45 kg of a slurry of ethylene glycol (manufactured by Nippon Shokubai Co., Ltd.) were sequentially supplied for four hours to an esterification reactor which was charged with about 123 kg of bis(hydroxyethyl)terephthalate and was maintained at a temperature of 250° C. and a pressure of 1.2×10⁵ Pa. After the supply of the high-purity terephthalic acid and the ethylene glycol was finished, an esterification reaction was further caused for one hour. Thereafter, 123 kg of the obtained esterification reaction product was transported to a polycondensation reactor.

Subsequently, ethylene glycol was further added to the polycondensation reactor to which the esterification reaction product was transported so as to reach 0.3 mass % with respect to the obtained polymer. After five minutes of stirring, an ethylene glycol solution of cobalt acetate and an ethylene glycol solution of manganese acetate were added to the obtained polymer so that a cobalt element-equivalent value of 30 ppm and a manganese element-equivalent value of 15 ppm were reached. Furthermore, after five minutes of stirring, a 2 mass % ethylene glycol solution of a titanium alkoxide compound was added to the obtained polymer so that a titanium element-equivalent value of 5 ppm was reached. After five minutes, a 10 mass % ethylene glycol solution of ethyl diethylphosphonoacetate was added to the obtained polymer so that a phosphorus element-equivalent value of 5 ppm was reached. Thereafter, while stirring a low polymer at 30 rpm, the reaction system was gradually increased in temperature from 250° C. to 285° C. and was decreased in pressure in the polycondensation reactor to 40 Pa. The periods of time until the final temperature and the final pressure were reached were both set to 60 minutes. At a time point at which a predetermined stirring torque was reached, the reaction system was purged with nitrogen, the pressure was returned to normal pressure, and the polycondensation reaction was stopped. In addition, the polymer obtained by the above-described polycondensation reaction was discharged to cold water in a strand shape, was immediately cut into polymer pellets (with a diameter of about 3 mm and a length of about 7 mm). The period of time until the predetermined stirring torque was reached after the start of depressurization was 3 hours.

Here, as the titanium alkoxide compound, the titanium alkoxide compound (Ti content=4.44 mass %) synthesized in Example 1 of paragraph [0083] of JP2005-340616A was used.

—Solid-Phase Polymerization—

The pellets obtained as above were held at a temperature of 220° C. for 30 hours in a vacuum container held at 40 Pa, thereby causing solid-phase polymerization.

### Example 1

### Production of Laminated Polyester Film

The pellets which had been subjected to solid-phase polymerization as described above were melted at 280° C. and were cast on a metallic drum, thereby producing an un-stretched polyethylene terephthalate (PET) film having a thickness of approximately 3 mm.

Thereafter, the un-stretched PET film was stretched 3.4 times in the machine direction (MD) at 90° C., and a corona discharge treatment was carried out on one surface of the uniaxially oriented PET film under the following conditions.

Next, an undercoat layer forming composition (composition 1) having the following composition was applied, using an inline coating method, onto the corona-treated surface of the uniaxially oriented PET film stretched in the MD direction after the MD stretching but before transverse direction (TD) stretching so that the amount of the undercoat layer forming composition applied reached 5.1 ml/m².

The PET film to which the undercoat layer forming composition (composition 1) was applied was stretched in the TD direction, thereby forming an undercoat layer having a thickness of 0.1 μm and a modulus of elasticity of 1.5 GPa. In addition, the TD stretching was carried out under conditions with a temperature of 105° C. and a stretching ratio of 4.5 times.

The PET film in which the undercoat layer was formed was subjected to a heat setting treatment on a film surface at 190° C. for 15 seconds, and the resultant was subjected to a thermal relaxation treatment at 190° C. in the MD and TD directions at an MD relaxation ratio of 5% and a TD relaxation ratio of 11%, thereby obtaining a 250 μm-thick biaxially oriented PET film in which the undercoat layer was formed (hereinafter, referred to as “laminated polyester film”). A small endothermic peak temperature of the obtained laminated polyester film was measured by differential scanning calorimetry (DSC), and as a result, the small endothermic peak temperature was 185° C.

(Corona Discharge Treatment)

The conditions for the corona discharge treatment carried out on one surface of the uniaxially oriented PET film are as follows.
Gap clearance between an electrode and a dielectric roll: 1.6 mm
Treatment frequency: 9.6 kHz
Treatment rate: 20 m/min
Treatment intensity: 0.375 kV·A·min/m²

Composition of Undercoat Layer Forming Composition (Composition 1))
Water dispersion liquid of acrylic resin 21.9 parts by mass
[AS-563A (manufactured by Daicel FineChem Ltd., a latex having a styrene skeleton in a solid content of 28 mass %]
Water-soluble oxazoline-based crosslinking agent 4.9 parts by mass
[EPOCROS (registered trademark) WS-700 manufactured by Nippon Shokubai Co., Ltd., solid content: 25 mass %]
Fluorine-based surfactant 0.1 parts by mass
Distilled water 73.1 parts by mass

A resin layer (B) and a resin layer (C) were formed on the laminated polyester film obtained as described above in the following manner.

First, a resin layer (B) forming composition was prepared to be provided with the following composition.

—Resin Layer (B) Forming Composition (B1)—
Water-soluble oxazoline-based crosslinking agent 3.3 parts by mass
[EPOCROS (registered trademark) WS-700 manufactured by Nippon Shokubai Co., Ltd., solid content: 25 mass %]
Water dispersion liquid of acrylic resin 7.4 parts by mass
[BONRON (registered trademark) XPS002 manufactured by Mitsui chemicals, Inc., solid content: 45 mass %, with a styrene skeleton in the structure]
Colloidal silica 10.2 parts by mass
[SNOWTEX (registered trademark) C manufactured by Nissan Chemical Industries, Ltd., solid content: 20 mass %]

Titanium dioxide dispersion liquid (solid content: 48.0 mass %) 30.5 parts by mass

Ammonium diphosphate (solid content: 35.0 mass %) 0.3 parts by mass

Fluorine-based surfactant (solid content: 2.0 mass %) 0.3 parts by mass

Distilled water 75.3 parts by mass

As the “Titanium dioxide dispersion liquid”, titanium dioxide dispersion liquid prepared in the following method was used.

˜Preparation of Titanium Dioxide Dispersion Liquid˜

Titanium dioxide having a volume average particle diameter of was 0.42 μm was dispersed to be provided with the following composition using a Dyno-Mill disperser, thereby preparing a titanium dioxide dispersion liquid. In addition, the volume average particle diameter of the titanium dioxide was measured using MICROTRACK FRA manufactured by Honeywell International, Inc.

˜Composition of Titanium Dioxide Dispersion Liquid˜
Titanium dioxide 455.8 parts by mass
[TIPAQUE (registered trademark) CR-95, manufactured by Ishihara Sangyo Kaisha, Ltd., powder]
Polyvinyl alcohol (PVA) aqueous solution 227.9 parts by mass
[PVA-105, manufactured by Kuraray Co., Ltd., solid content 10 mass %]
Dispersant 5.5 parts by mass
[DEMOL EP, manufactured by Kao Corporation, solid content: 25 mass %]
Distilled water 310.8 parts by mass

The obtained resin layer (B) forming composition was applied onto the surface of the laminated polyester film on which the undercoat layer was formed so that the film thickness (dry film thickness) after drying reached 0.9 μm, and the resultant was dried at 170° C. for two minutes, thereby forming a resin layer (B).

Thereafter, the resin layer (C) forming composition was applied onto the surface of the resin layer (B) so that the film thickness after drying reached 0.3 μm, and the resultant was dried, thereby forming a resin layer (C).

The composition of the resin layer (C) forming composition is as follows. EMALEX 110 was diluted in a mixed solvent of water and ethanol at a ratio of 2:1 to reach 2 mass % for use.

—Resin Layer (C) Forming Composition (C1) of Example 1—
Water-soluble oxazoline-based crosslinking agent 1.2 parts by mass
[EPOCROS (registered trademark) WS-700 manufactured by Nippon Shokubai Co., Ltd., solid content: 25 mass %]
Water dispersion liquid of polyolefin resin 9.4 parts by mass
[ELEVES (registered trademark) SE-1013N manufactured by Unitika Ltd., solid content: 20.2 mass %]
Water dispersion liquid of acrylic resin 1.7 parts by mass
[AS-563A manufactured by Daicel FineChem Ltd., a latex having a styrene skeleton in a solid content of 28 mass %]
Surfactant 4.2 parts by mass
[EMALEX (registered trademark) 110, manufactured by Nihon Emulsion Co., Ltd., solid content: 2 mass %]
Distilled water 83.4 parts by mass

Furthermore, on the side of the laminated polyester film on which the undercoat layer was not formed, a coating layer (D) and a coating layer (E) were sequentially formed as weather-resistant layers by using a coating layer (D) forming composition and a coating layer (E) forming composition having the following compositions, thereby producing a solar cell protective sheet.

—Formation of Coating Layer (D)—

—Preparation of Coating Layer (D) Forming Composition—

Individual components described below were mixed together, thereby preparing the coating layer (D) forming composition (D1). As the “titanium dioxide dispersion liquid” described below, the same titanium dioxide dispersion liquid as that used for the preparation of the resin layer (B) was used.

—Coating Layer (D) Forming Composition (D1)—
silicone-based compound 381.7 parts by mass
[CERANATE (registered trademark) WSA1070 manufactured by DIC Corporation, solid content: 38 mass %]
Polyoxyalkylene alkyl ether 13.1 parts by mass
[NAROACTY (registered trademark) CL-95 manufactured by Sanyo Chemical Industries, ltd., solid content: 1 mass %]
Water-soluble oxazoline-based crosslinking agent 105.1 parts by mass
[EPOCROS (registered trademark) WS-700 manufactured by Nippon Shokubai Co., Ltd., solid content: 25 mass %]
Distilled water 14.3 parts by mass
Titanium dioxide dispersion liquid (solid content: 48 mass %) 483.4 parts by mass

Formation of Coating Layer (D)

The obtained coating layer (D) forming composition was applied onto the rear surface (surface on which the resin layer (B) was not formed) of the laminated polyester film so that the amount of the binder applied reached 4.7 g/m² and the amount of titanium dioxide applied reached 5.6 g/m² and was dried at 170° C. for two minutes, thereby forming a coating layer (D) having a thickness of 20 μm after the drying.

Formation of Coating Layer (E)

Coating liquids for the coating layer (E) forming composition (E1) described below were applied to the surface of the coating layer (D) so that the amount of the binder applied reached 1.3 g/m², and were dried at 175° C. for two minutes, thereby forming a 1 μm-thick coating layer (E).

—Coating Layer (E) Forming Composition (E1)—
Fluorine-based resin 345.0 parts by mass
[OBBLIGATO (registered trademark) SW0011F manufactured by AGC Coat-Tech Co., Ltd., solid content: 36 mass %]
Colloidal silica 3.9 parts by mass
[SNOWTEX (registered trademark) UP manufactured by Nissan Chemical Industries, Ltd., solid content: 20 mass %]
Silane coupling agent 78.5 parts by mass
[TSL8340, Momentive Performance Materials Inc., solid content: 1 mass %]
Synthetic wax 207.0 parts by mass
[CHEMIPAL (registered trademark) W950 manufactured by Mitsui Chemicals, Inc., solid content: 5 mass %]
Polyoxyalkylene alkyl ether 60.0 parts by mass
[NAROACTY (registered trademark) CL-95 manufactured by Sanyo Chemical Industries, ltd., solid content: 1 mass %]
Carbodiimide compound 62.3 parts by mass
[CARBODILITE (registered trademark) V-02-L2 manufactured by Nisshinbo Chemical Inc., solid content: 20 mass %]
Distilled water 242.8 parts by mass

### Examples 2 to 17 and Comparative Examples 1 to 12

Examples 2 to 17 and Comparative Examples 1 to 12 were produced in the same manner as that in Example 1 except that the undercoat layer forming composition, the resin layer (B) forming composition, the resin layer (C) forming composition, the small endothermic peak temperature, and the heat setting temperature were changed as shown in Table 4.

The following evaluations were carried out on each of the examples and the comparative examples. The evaluation results are shown in Table 4.

Details of the undercoat layer forming composition, the resin layer (B) forming composition, and the resin layer (C) forming composition are shown in Tables 1 to 3 below.

TABLE 1

| | | Compo- | Compo- | Compo- | Compo- | Compo- | Compo- | Compo- | Compo- | Compo- | Compo- | Compo- | Compo- | Compo- |
|---|---|---|---|---|---|---|---|---|---|---|---|---|---|---|
| | Concen- | sition | sition | sition | sition | sition | sition | sition | sition | sition | sition | sition | sition | sition |
| Materials | tration | 1 | 2 | 3 | 4 | 5 | 6 | 7 | 8 | 9 | 10 | 11 | 12 | 13 |
| Water | — | 73.1 | 72.3 | 71.0 | 68.9 | 66.7 | 64.5 | 81.3 | 82.4 | 74.6 | 73.1 | 81.6 | 78.7 | 74.6 |
| EPOCROS | 25 | 4.9 | 4.9 | 4.9 | 4.9 | 4.9 | 4.9 | 4.9 | 4.9 | 4.9 | 4.9 | 4.9 | 4.9 | 4.9 |
| WS700 | | | | | | | | | | | | | | |
| ELEVES | 20.2 | | 3.0 | 7.6 | 15.2 | 22.8 | 30.4 | | | | | | | |
| SE-1013N | | | | | | | | | | | | | | |
| AS-563A | 28 | 21.9 | 19.7 | 16.4 | 10.9 | 5.5 | | | | | | | | |
| BONRON | 45 | | | | | | | 13.7 | | | | | | |
| XPS002 | | | | | | | | | | | | | | |
| JONCRYL | 49 | | | | | | | | 12.6 | | | | | |
| PDX-7341 | | | | | | | | | | | | | | |
| HARDLEN | 30 | | | | | | | | | 20.4 | | | | |
| NZ-1001 | | | | | | | | | | | | | | |
| HITECH | 28 | | | | | | | | | | 21.9 | | | |
| S3148 | | | | | | | | | | | | | | |
| SUPERFLEX | 46 | | | | | | | | | | | 13.4 | | |
| 500M | | | | | | | | | | | | | | |
| SUPERFLEX | 37.6 | | | | | | | | | | | | 16.3 | |
| 460S | | | | | | | | | | | | | | |
| FINETEX | 30 | | | | | | | | | | | | | 20.4 |
| ES2200 | | | | | | | | | | | | | | |
| Fluorine-based | 2 | 0.1 | 0.1 | 0.1 | 0.1 | 0.1 | 0.1 | 0.1 | 0.1 | 0.1 | 0.1 | 0.1 | 0.1 | 0.1 |
| surfactant | | | | | | | | | | | | | | |

| | | | | | | | | | | | | | |
|---|---|---|---|---|---|---|---|---|---|---|---|---|---|
| Total | 100 | 100 | 100 | 100 | 100 | 100 | 100 | 100 | 100 | 100 | 100 | 100 | 100 |

Items in Table 1 will be described.
JONCRYL (registered trademark) PDX-7341: acrylic resin, manufactured by BASF SE
HARDLEN (registered trademark) NZ-1001: polyolefin resin, manufactured by Toyobo Co., Ltd.
HITECH 53148: polyolefin resin, manufactured by TOHO CHEMICAL INDUSTRY Co., Ltd.
SUPERFLEX (registered trademark) 500N: polyurethane resin, manufactured by DKS Co. Ltd.
SUPERFLEX (registered trademark) 460S: polyurethane resin, manufactured by DKS Co. Ltd.
FINETEX (registered trademark) ES2200: polyester resin, manufactured by DIC Corporation

TABLE 2

| Materials | Concentration | B1 | B2 |
|---|---|---|---|
| Water | — | 75.3 | 7.4 |
| SNOWTEX C | 20.0 | 10.2 | — |
| Titanium oxide dispersion | 49.0 | 3.3 | 30.5 |
| liquid | | | |
| EPOCROS WS700 | 25.0 | 3.3 | 12.5 |
| Ammonium diphosphate | 35.0 | 0.3 | 0.8 |
| BONRON XPS002 | 45.0 | 7.4 | — |
| ELEVES SE-1013N | 20.2 | — | 40.6 |
| AS-563A | 28.0 | — | 7.8 |
| Fluorine-based surfactant | 2.0 | 0.3 | 0.4 |

| | | |
|---|---|---|
| Total | 100.0 | 100.0 |

TABLE 3

| Materials | Concentration | C1 | C2 |
|---|---|---|---|
| Water | — | 83.4 | 73.7 |
| EPOCROS WS700 | 25.0 | 1.2 | 4.3 |
| ELEVES SE-1013N | 20.2 | 9.4 | 19.8 |
| AS-563A | 28.0 | 1.7 | 0.9 |
| EMALEX110 | 10.0 | 4.2 | — |
| NAROACTY CL-95 | 1.0 | — | 1.0 |
| Fluorine-based surfactant | 2.0 | — | 0.2 |

| | | |
|---|---|---|
| Total | 100.0 | 100.0 |

### (Cohesive Fracture Resistance)

Cohesive fracture resistance was evaluated in the following method.

The solar cell protective sheet obtained in each of the examples was cut into 1.0 cm (TD direction)×30 cm (MD direction). Next, two EVA films (Hangzhou, F806) were laminated on a glass plate having a size of 20 cm×20 cm×0.3 cm in thickness.

At a distance of 10 cm to 20 cm from one end portion of the glass plate on which the EVA films were laminated, a polyethylene terephthalate (PET) film (CERAPEEL (registered trademark) manufactured by Toray Industries, Inc.) treated with a peeling agent was laminated, the other end portion and an end portion in the MD direction of the solar cell protective sheet were aligned with each other and the solar cell protective sheet was placed so as to cause the resin layer (C) to come into contact with the EVA films, and the resultant was laminated using a vacuum laminator (LAMINATOR 05055 manufactured by Nisshinbo Mechatronics Inc.) under conditions with a temperature of 145° C., evacuation for 4 minutes, and pressurization for 10 minutes, thereby producing a sample.

The solar cell protective sheet attached to the EVA was adjusted in humidity for 24 hours or longer under conditions with a temperature of 23° C. and a relative humidity of 50%, and thereafter a portion with a width of 1.0 cm in the sample produced above was subjected to a tensile test at a peel angle of 180° by a tensile tester (TENSILON manufactured by A&D Company) at a rate of 100 mm/min.

In addition, on the base of the following evaluation criteria, fracture stress was evaluated. A higher fracture stress indicates higher cohesive fracture resistance in the evaluation.

### —Evaluation Criteria—

5: The stress of a peak top is 9 N/mm or higher.

4: The stress of a peak top is 8 N/mm or higher and lower than 9 N/mm.

3: The stress of a peak top is 6 N/mm or higher and lower than 8 N/mm.

2: The stress of a peak top is 4 N/mm or higher and lower than 6 N/mm.

1: The stress of a peak top is 0 N/mm or higher and lower than 4 N/mm.

### (Weather Resistance)

Weather resistance (wet heat stability) was evaluated according to the following criteria by measuring an elongation at break retention half-life in the following method.

### —Elongation at Break Retention Half-Life—

A preservation treatment (heating treatment) was carried out on the obtained laminated polyester film under conditions with a temperature of 120° C. and a relative humidity of 100%, and a preservation time (elongation at break retention half-life) for which the elongation at break (%) of the laminated polyester film after the preservation treatment was reduced to 50% of the elongation at break (%) of the laminated polyester film before the preservation treatment was measured.

A longer elongation at break retention half-life indicates better wet heat stability of the laminated polyester film.

### —Evaluation Criteria—

5: An elongation at break half-like time is 100 hours or longer.

4: An elongation at break half-like time is 90 hours or longer and shorter than 100 hours.

3: An elongation at break half-like time is 80 hours or longer and shorter than 90 hours.

2: An elongation at break half-like time is 70 hours or longer and shorter than 80 hours.

1: An elongation at break half-like time is shorter than 70 hours.

TABLE 4

| | Undercoat layer | | | | | | | | |
|---|---|---|---|---|---|---|---|---|---|
| | | | Mixing | | Modulus | Resin layer (B) | | Resin layer (C) | |
| | | | ratio | Dry film | of | | Dry film | | Dry film |
| | | | (mass | thickness | elasticity | | thickness | | thickness |
| | Composition | Resin kind | ratio) | (μm) | (GPa) | Composition | (μm) | Composition | (μm) |
| Example 1 | Composition 1 | Acrylic | 100 | 0.1 | 1.5 | B1 | 0.9 | C1 | 0.3 |
| Example 2 | Composition 2 | Acrylic | 90 | 0.1 | 1.3 | B1 | 0.9 | C1 | 0.3 |
| | | Olefin-based | 10 | | | | | | |
| Example 3 | Composition 3 | Acrylic | 75 | 0.1 | 1.1 | B1 | 0.9 | C1 | 0.3 |
| | | Olefin-based | 25 | | | | | | |
| Example 4 | Composition 4 | Acrylic | 50 | 0.1 | 0.8 | B1 | 0.9 | C1 | 0.3 |
| | | Olefin-based | 50 | | | | | | |
| Comparative | Composition 5 | Acrylic | 25 | 0.1 | 0.2 | B1 | 0.9 | C1 | 0.3 |
| Example 1 | | Olefin-based | 75 | | | | | | |
| Comparative | Composition 6 | Olefin-based | 100 | 0.1 | 0.1 | B1 | 0.9 | C1 | 0.3 |
| Example 2 | | | | | | | | | |
| Comparative | Composition 7 | Acrylic | 100 | 0.1 | 0.6 | B1 | 0.9 | C1 | 0.3 |
| Example 3 | | | | | | | | | |
| Comparative | Composition 8 | Acrylic | 100 | 0.1 | 0.1 | B1 | 0.9 | C1 | 0.3 |
| Example 4 | | | | | | | | | |
| Comparative | Composition 9 | Olefin-based | 100 | 0.1 | 0.6 | B1 | 0.9 | C1 | 0.3 |
| Example 5 | | | | | | | | | |
| Comparative | Composition 10 | Olefin-based | 100 | 0.1 | 0.1 | B1 | 0.9 | C1 | 0.3 |
| Example 6 | | | | | | | | | |
| Comparative | Composition 11 | Urethane-based | 100 | 0.1 | 0.1 | B1 | 0.9 | C1 | 0.3 |
| Example 7 | | | | | | | | | |
| Comparative | Composition 12 | Urethane-based | 100 | 0.1 | 0.2 | B1 | 0.9 | C1 | 0.3 |
| Example 8 | | | | | | | | | |
| Example 5 | Composition 13 | Polyester-based | 100 | 0.1 | 1.4 | B1 | 0.9 | C1 | 0.3 |
| Comparative | Composition 1 | Acrylic | 100 | 0.1 | 1.5 | B1 | 0.9 | C1 | 0.3 |
| Example 9 | | | | | | | | | |
| Example 6 | Composition 1 | Acrylic | 100 | 0.1 | 1.5 | B1 | 0.9 | C1 | 0.3 |
| Example 7 | Composition 1 | Acrylic | 100 | 0.1 | 1.5 | B1 | 0.9 | C1 | 0.3 |
| Example 8 | Composition 1 | Acrylic | 100 | 0.1 | 1.5 | B1 | 0.9 | C1 | 0.3 |
| Example 9 | Composition 1 | Acrylic | 100 | 0.1 | 1.5 | B1 | 0.9 | C1 | 0.3 |
| Example 10 | Composition 1 | Acrylic | 100 | 0.1 | 1.5 | B1 | 0.9 | C1 | 0.3 |
| Example 11 | Composition 1 | Acrylic | 100 | 0.1 | 1.5 | B1 | 0.9 | C1 | 0.3 |
| Comparative | Composition 1 | Acrylic | 100 | 0.1 | 1.5 | B1 | 0.9 | C1 | 0.3 |
| Example 10 | | | | | | | | | |
| Comparative | Composition 1 | Acrylic | 100 | 0.1 | 1.5 | B2 | 6.5 | C2 | 0.5 |
| Example 11 | | | | | | | | | |
| Example 12 | Composition 1 | Acrylic | 100 | 0.1 | 1.5 | B2 | 6.5 | C2 | 0.5 |
| Example 13 | Composition 1 | Acrylic | 100 | 0.1 | 1.5 | B2 | 6.5 | C2 | 0.5 |
| Example 14 | Composition 1 | Acrylic | 100 | 0.1 | 1.5 | B2 | 6.5 | C2 | 0.5 |
| Example 15 | Composition 1 | Acrylic | 100 | 0.1 | 1.5 | B2 | 6.5 | C2 | 0.5 |
| Example 16 | Composition 1 | Acrylic | 100 | 0.1 | 1.5 | B2 | 6.5 | C2 | 0.5 |
| Example 17 | Composition 1 | Acrylic | 100 | 0.1 | 1.5 | B2 | 6.5 | C2 | 0.5 |
| Comparative | Composition 1 | Acrylic | 100 | 0.1 | 1.5 | B2 | 6.5 | C2 | 0.5 |
| Example 12 | | | | | | | | | |

| | | | | | Biaxially | Heat setting | | |
|---|---|---|---|---|---|---|---|---|
| | Coating layer (D) | | Coating layer (E) | | oriented film | temperature | Evaluation results | |
| | | Dry film | | Dry film | Small endothermic | Set | Cohesive | |
| | | thickness | | thickness | peak temperature | temperature | fracture | Weather |
| | Composition | (μm) | Composition | (μm) | (° C.) | (° C.) | resistance | resistance |
| Example 1 | D1 | 20 | E1 | 1 | 185 | 190 | 5 | 5 |
| Example 2 | D1 | 20 | E1 | 1 | 185 | 190 | 4 | 5 |
| Example 3 | D1 | 20 | E1 | 1 | 185 | 190 | 4 | 5 |
| Example 4 | D1 | 20 | E1 | 1 | 185 | 190 | 3 | 5 |
| Comparative | D1 | 20 | E1 | 1 | 185 | 190 | 2 | 5 |
| Example 1 | | | | | | | | |
| Comparative | D1 | 20 | E1 | 1 | 185 | 190 | 1 | 5 |
| Example 2 | | | | | | | | |
| Comparative | D1 | 20 | E1 | 1 | 185 | 190 | 1 | 5 |
| Example 3 | | | | | | | | |
| Comparative | D1 | 20 | E1 | 1 | 185 | 190 | 1 | 5 |
| Example 4 | | | | | | | | |
| Comparative | D1 | 20 | E1 | 1 | 185 | 190 | 1 | 5 |
| Example 5 | | | | | | | | |
| Comparative | D1 | 20 | E1 | 1 | 185 | 190 | 1 | 5 |
| Example 6 | | | | | | | | |
| Comparative | D1 | 20 | E1 | 1 | 185 | 190 | 1 | 5 |
| Example 7 | | | | | | | | |
| Comparative | D1 | 20 | E1 | 1 | 185 | 190 | 1 | 5 |
| Example 8 | | | | | | | | |
| Example 5 | D1 | 20 | E1 | 1 | 185 | 190 | 3 | 5 |
| Comparative | D1 | 20 | E1 | 1 | 220 | 225 | 5 | 2 |
| Example 9 | | | | | | | | |
| Example 6 | D1 | 20 | E1 | 1 | 210 | 215 | 5 | 3 |
| Example 7 | D1 | 20 | E1 | 1 | 200 | 205 | 5 | 4 |
| Example 8 | D1 | 20 | E1 | 1 | 190 | 195 | 5 | 5 |
| Example 9 | D1 | 20 | E1 | 1 | 180 | 185 | 5 | 5 |
| Example 10 | D1 | 20 | E1 | 1 | 170 | 175 | 5 | 4 |
| Example 11 | D1 | 20 | E1 | 1 | 160 | 165 | 3 | 3 |
| Comparative | D1 | 20 | E1 | 1 | 150 | 155 | 1 | 2 |
| Example 10 | | | | | | | | |
| Comparative | D1 | 20 | E1 | 1 | 220 | 225 | 5 | 2 |
| Example 11 | | | | | | | | |
| Example 12 | D1 | 20 | E1 | 1 | 210 | 215 | 5 | 3 |
| Example 13 | D1 | 20 | E1 | 1 | 200 | 205 | 5 | 4 |
| Example 14 | D1 | 20 | E1 | 1 | 190 | 195 | 5 | 5 |
| Example 15 | D1 | 20 | E1 | 1 | 180 | 185 | 5 | 5 |
| Example 16 | D1 | 20 | E1 | 1 | 170 | 175 | 5 | 4 |
| Example 17 | D1 | 20 | E1 | 1 | 160 | 165 | 2 | 3 |
| Comparative | D1 | 20 | E1 | 1 | 150 | 155 | 1 | 2 |
| Example 12 | | | | | | | | |

### Examples 18 to 34

### Production of Solar Cell Module

Using the solar cell protective sheets of Examples 1 to 17, solar cell modules of Examples 18 to 34 were produced in the following method.

A 3.2 mm-thick reinforced glass plate (transparent base material), an EVA sheet (sealing material) (SC50B manufactured by Mitsui Chemicals, Inc.), a crystalline solar cell (solar cell element), an EVA sheet (SC50B manufactured by Mitsui Chemicals, Inc.), and the solar cell protective sheet of any one of Examples 1 to 13 were superimposed in this order, and were hot-pressed using a vacuum laminator (vacuum laminator manufactured by Nisshinbo Mechatronics Inc.) such that the individual members and the EVA sheets were adhered. In this manner, a solar cell module was produced.

### EVALUATION

A power generation operation test was conducted on each of the solar cell modules of Examples 18 to 34 produced as above, and the solar cell modules exhibited favorable power generation performance as solar cells.

The entirety of the disclosure of Japanese Patent Application No. 2014-156943 is incorporated herein by reference.

Publications, patent applications, and technical standards described in this specification are incorporated herein by reference to the same degree as in a case where those publications, patent applications, and technical standards are individually described in detail.

What is claimed is:

1. A laminated polyester film comprising:
a biaxially oriented polyester film which is produced by stretching an un-stretched polyester film in a first direction and stretching the resultant in a second direction perpendicular to the first direction along a film surface and has a small endothermic peak temperature of 160° C. or higher and 210° C. or lower, which is derived from a heat setting temperature measured by differential scanning calorimetry; and
an undercoat layer which is formed by applying an undercoat layer forming composition onto one surface of the polyester film stretched in the first direction before being stretched in the second direction, and stretching the resultant in the second direction, and has a modulus of elasticity of 0.7 GPa or higher.

2. The laminated polyester film according to claim 1,
wherein the undercoat layer includes an acrylic resin, and
the content of the acrylic resin in a resin component included in the undercoat layer is 50 mass % or more.

3. The laminated polyester film according to claim 2,
wherein the content of the acrylic resin in the resin component included in the undercoat layer is 75 mass % or more.

4. The laminated polyester film according to claim 2,
wherein the acrylic resin included in the undercoat layer has a styrene skeleton.

5. The laminated polyester film according to claim 1,
wherein the modulus of elasticity of the undercoat layer is 1.0 GPa or higher.

6. The laminated polyester film according to claim 1,
wherein the modulus of elasticity of the undercoat layer is 1.3 GPa or higher.

7. The laminated polyester film according to claim 1,
wherein the small endothermic peak temperature of the biaxially oriented polyester film is 170° C. or higher and 200° C. or lower.

8. The laminated polyester film according to claim 1,
wherein the small endothermic peak temperature of the biaxially oriented polyester film is 180° C. or higher and 190° C. or lower.

9. The laminated polyester film according to claim 1,
wherein the undercoat layer further includes an oxazoline-based crosslinking agent.

10. A solar cell protective sheet comprising:
the laminated polyester film according to claim 1; and
a resin layer including an acrylic resin disposed on an undercoat layer of the laminated polyester film.

11. The solar cell protective sheet according to claim 10,
wherein the resin layer has a structure in which at least two layers are laminated, and an outermost layer which is farthest from the laminated polyester film includes an acrylic resin and a polyolefin resin.

12. The solar cell protective sheet according to claim 10,
wherein a weather-resistant layer is provided on a side of the laminated polyester film opposite to a side on which the undercoat layer is provided.

13. The solar cell protective sheet according to claim 12,
wherein the weather-resistant layer has a structure in which at least two layers are laminated, and a weather-resistant layer farthest from the laminated polyester film includes a fluorine-based resin.

14. A solar cell module comprising:
the solar cell protective sheet according to claim 10.

15. A production method of a laminated polyester film comprising:
a process of stretching an un-stretched polyester film in a first direction;
a process of applying an undercoat layer forming composition onto one surface of the polyester film stretched in the first direction;
a process of forming an undercoat layer having a modulus of elasticity of 0.7 GPa or higher by stretching the polyester film, to which the undercoat layer forming composition is applied, in a second direction perpendicular to the first direction along a film surface; and
a heat setting process of carrying out a heat setting treatment on the polyester film in which the undercoat layer is formed, at 165° C. or higher and 215° C. or lower,
wherein a biaxially oriented polyester film in which the undercoat layer is formed is produced.
